(19) United States
(12) Patent Application Publication
(10) Pub. No.: US 2024/0266245 A1
(43) Pub. Date: Aug. 8, 2024

(54) PACKAGE STRUCTURE AND MANUFACTURING METHOD THEREOF

(71) Applicant: Beijing Youzhuju Network Technology Co., Ltd., Beijing (CN)

(72) Inventors: Sijie LI, Beijing (CN); Haixin HUANG, Beijing (CN); Meng MEI, Beijing (CN); Jifeng LI, Beijing (CN); Jian WANG, Beijing (CN)

(21) Appl. No.: 18/431,780

(22) Filed: Feb. 2, 2024

(30) Foreign Application Priority Data
Feb. 3, 2023 (CN) 202310128579.9

(51) Int. Cl. H01L 23/367; H01L 21/48

(52) U.S. Cl. CPC H01L 23/3675; H01L 21/4878

(57) ABSTRACT

The embodiments of the disclosure provides a package structure and a manufacturing method thereof, the package structure includes: a die, including a substrate and a device layer, wherein the substrate has a front side and a back side opposite to each other in a first direction perpendicular to a main surface of the die, and the device layer is at the front side of the substrate; a thermal interface material layer, on the back side of the substrate; and a thermal dissipation component, attached to the die through the thermal interface material layer, the die further includes at least one of a heat dissipation filling structure and a substrate recess, the heat dissipation filling structure is embedded in the substrate and has an exposed part exposed at a sidewall of the substrate; the substrate recess is recessed from the back side of the substrate towards the device layer.

### CROSS-REFERENCE TO RELATED APPLICATION(S)

The present application claims the priority of Chinese Patent Application No. 202310128579.9 filed on Feb. 3, 2023, and the disclosure of the above-mentioned Chinese Patent Application is incorporated herein by reference as a part of the present application.

### TECHNICAL FIELD

Embodiments of the present disclosure relate to a package structure and a manufacturing method thereof.

### BACKGROUND

Integrated circuit (IC) chips are widely used in various electronic devices, and can be packaged by means of semiconductor packaging technology. Chips may generate heat during operation. In order to ensure reliable operation of chips and devices including the same, the heat of chips need to be effectively dissipated. For example, with the rapid development of artificial intelligence (AI) and new energy electric vehicles, the application of high-power integrated circuit chips is more and more extensive. However, with the increase of power, the heat generated during the operation of the chip increases, which causes the risk of chip damage due to excessive temperature to be increasingly raised. In order to ensure the continuous and reliable operation of the chip, how to reduce the thermal resistance of the chip to optimize the heat dissipation thereof has become an important topic in the application of integrated circuit chips (especially high-power integrated circuit chips).

### SUMMARY

At least one embodiment of the present disclosure provides a package structure, including: a die, including a substrate and a device layer, wherein the substrate has a front side and a back side opposite to each other in a first direction perpendicular to a main surface of the die, and the device layer is disposed at the front side of the substrate; a thermal interface material layer, disposed on the back side of the substrate; and a thermal dissipation component, attached to the die through the thermal interface material layer, wherein the die further includes at least one of a heat dissipation filling structure and a substrate recess, the heat dissipation filling structure is embedded in the substrate and has an exposed part exposed at a sidewall of the substrate; the substrate recess is recessed from the back side of the substrate towards the device layer.

At least one embodiment of the present disclosure provides a method of manufacturing a package structure, including: providing a die including a substrate and a device layer, wherein the substrate has a front side and a back side opposite to each other in a first direction perpendicular to a main surface of the die, and the device layer is disposed at the front side of the substrate; forming at least one of a heat dissipation filling structure and a substrate recess in the substrate of the die, including: performing a first cutting process on the die to cut and remove a part of the die, and forming at least one of a trench and the substrate recess in the substrate of the die, wherein the trench is configured for being filled with the heat dissipation filling structure; disposing a thermal interface material layer on the back side of the substrate; and attaching a thermal dissipation component to the die through the thermal interface material layer.

### BRIEF DESCRIPTION OF DRAWINGS

In order to more clearly explain the technical solution of the embodiments of the present disclosure, the drawings of the embodiments will be briefly introduced below. It is obvious that the drawings in the following description only relate to some embodiments of the present disclosure, but do not intend to limit the present disclosure.

FIG. 1A and FIG. 1B illustrate schematic cross-sectional views of a package structure according to some embodiments of the present disclosure, and FIG. 1C illustrates a schematic top view of a die in the package structure according to some embodiments of the present disclosure.

FIG. 2A illustrates a schematic cross-sectional view of a package structure according to some embodiments of the present disclosure, and FIG. 2B, FIG. 2C, and FIG. 2D illustrate schematic plan views of a die, a thermal interface material layer and a heat dissipation protrusion in the package structure according to some embodiments of the present disclosure.

FIG. 3A, FIG. 3B, FIG. 4A, FIG. 4B, FIG. 5A, FIG. 5B, FIG. 6A, FIG. 6B, FIG. 7A, FIG. 7B, FIG. 8, FIG. 9, FIG. 10, and FIG. 11 illustrate schematic top views and cross-sectional views of structures formed at various steps in a manufacturing method of a package structure according to some embodiments of the present disclosure.

FIG. 12A and FIG. 12B illustrate schematic cross-sectional views of a package structure according to some other embodiments of the present disclosure.

FIG. 13A, FIG. 13B, FIG. 13C illustrate schematic cross-sectional views of a package structure according to some other embodiments of the present disclosure, and FIG. 13D illustrates a schematic top view of a die in the package structure according to some other embodiments of the present disclosure.

FIG. 14A illustrates a schematic cross-sectional view of a package structure according to some other embodiments of the present disclosure, and FIG. 14B illustrates a schematic top view of a die in the package structure according to some other embodiments of the present disclosure.

FIG. 15A and FIG. 15B illustrate schematic cross-sectional views of a package structure according to some other embodiments of the present disclosure.

FIG. 16A illustrates a schematic cross-sectional view of a package structure according to some other embodiments of the present disclosure, and FIG. 16B illustrates a schematic top view of a die in the package structure according to some other embodiments of the present disclosure.

FIG. 17 illustrates a schematic cross-sectional view of a package structure according to some other embodiments of the present disclosure.

### DETAILED DESCRIPTION

In order to make objects, technical solutions and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

Unless otherwise specified, the technical terms or scientific terms used in the disclosure shall have normal meanings understood by those skilled in the art. The words “first”, “second” and the like used in the disclosure do not indicate the sequence, the number or the importance but are only used for distinguishing different components. The word “comprise”, “include” or the like only indicates that an element or a component before the word contains elements or components listed after the word and equivalents thereof, not excluding other elements or components. The words “connection” “connected”, and the like are not limited to physical or mechanical connection but may include electrical connection, either directly or indirectly.

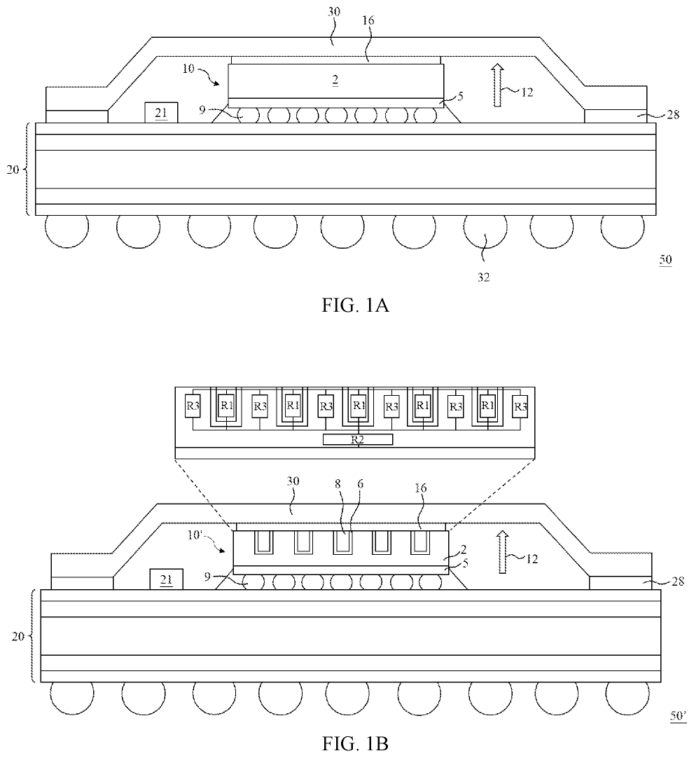

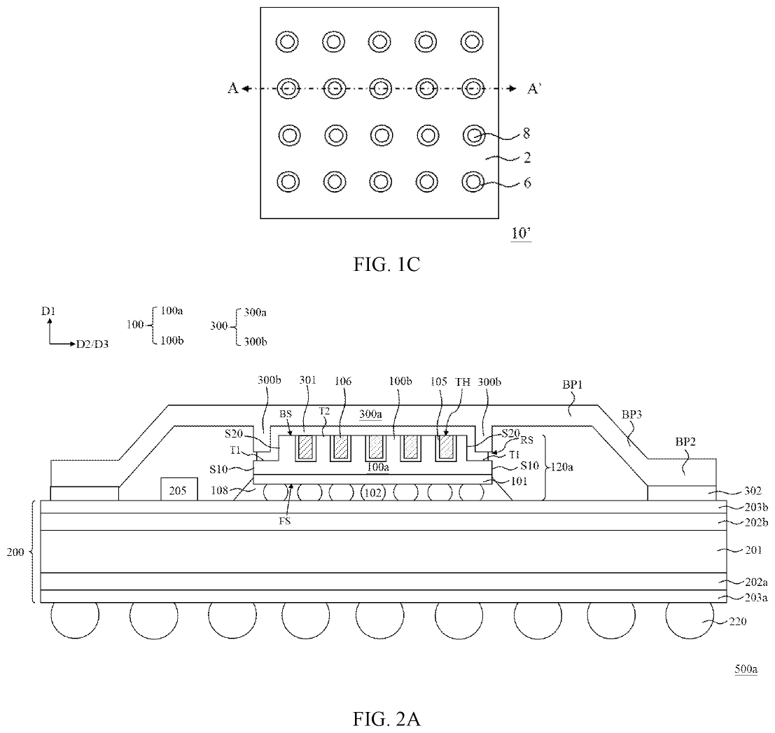

FIG. 1A and FIG. 1B illustrate schematic cross-sectional views of a package structure according to some embodiments of the present disclosure; FIG. 1C illustrates a schematic top view of a die in the package structure illustrated in FIG. 1B according to some embodiments of the present disclosure, and the cross-sectional view of the die in FIG. 1B is taken along the line A-A′ of FIG. 1C.

Referring to FIG. 1A, in some embodiments, a package structure 50 includes a die 10, a package substrate 20 and a heat dissipation lid 30. The die 10 is an integrated circuit (IC) chip and includes a substrate 2 and a device layer 5. The substrate 2 is a semiconductor substrate, such as a silicon substrate. The device layer 5 may include active devices such as transistors and passive devices such as capacitors. In some embodiments, the device layer 5 may also be referred to as an active device layer or an active layer. In some embodiments, the device layer 5 may be referred to as a functional area of the die, and the substrate 6 may be referred to as a non-functional area of the die. Conductive bumps 9 are disposed on a side of the device layer 9 away from the substrate 2 to provide electrical connection between the die 10 and the package substrate 20. A plurality of conductive bumps 32 are disposed on a side of the package substrate 20 opposite to the die 10, and configured for external connection of the package structure 50.

The heat dissipation lid 30 is mounted on the package substrate 20 through an adhesive layer 28, and is attached to the substrate 2 of the die 10 through a thermal interface material (TIM) layer 16 for heat dissipation of the die 10. For example, the heat of the die 10 is conducted to the thermal interface material layer 16 along a direction perpendicular to a main surface of the substrate 2, and then conducted to the heat dissipation lid 30 through the thermal interface material layer 16, and further dissipated to the outside through the heat dissipation lid 30. The smaller the thermal resistance of the die 10, the better the heat dissipation performance thereof. The details are set forth as follows.

Thermal resistance refers to the ability of an object to resist heat transfer. When heat is transferred on the object, the thermal resistance is a ratio of a temperature difference between two ends of the object to a heat source power. The unit of thermal resistance is K/W or ° C./W, that is, the thermal resistance can be calculated by the following formula (a):

$${R}_{θ} = \frac{{T}_{2} - {T}_{1}}{{P}_{H}} , \qquad ( a )$$

wherein R_{θ} is an absolute thermal resistance of the material along a heat flux direction, and the unit is (K/W); T₁ and T₂ are temperatures of one end and the other end of the object in the heat flux direction, respectively, that is, the temperatures of two ends of the object opposite to each other in the heat flux direction, and the units are both K; P_{H} is the power of the heat source generating the heat flux, and the unit is W.

FIG. 1A schematically illustrates the heat flux direction 12 of the die 10 (i.e., the vertical direction illustrated in the figure), which includes a direction substantially perpendicular to a main surface of the die 10 and the substrate 2 thereof. According to the above formula (a), under the condition of a constant heat source power, a smaller thermal resistance of the die represents that the temperature difference between two ends of the die is smaller in the heat flux direction 12, and the heat generated by the die during operation is conducted faster from one end to the other end, so that the heat of the die can be dissipated away faster, and the die damage or life shortening caused by heat accumulation can be avoided.

The following formula (b) can be derived from Fourier law based on heat conduction:

$${R}_{θ} = \frac{L}{k A} , \qquad ( b )$$

wherein R_{θ} is the absolute thermal resistance of the material along the heat flux direction, and the unit is (K/W); L is a length (for example, a thickness) of the object along the heat flux direction, and the unit is m; k is a thermal conductivity of the material, and the unit is (W/(m·K)); A is a cross-sectional area of the object in a direction perpendicular to the heat flux direction, and the unit is m².

According to the above formula (b), the thermal resistance of the die 10 is directly proportional to the thickness of the die 10 in the heat flux direction 12, and is inversely proportional to the thermal conductivity of the material of the die and the cross-sectional area of the die in a direction perpendicular to the heat flux direction 12 (that is, the cross-sectional area in the horizontal direction illustrated in the figure). Therefore, in the design stage of the die, in the case that the power of the die is constant, either one of reducing the thickness of the die, increasing the thermal conductivity of the die and expanding the cross-sectional area of the die (that is, the heat dissipation area) can effectively reduce the thermal resistance of the die.

FIG. 1B illustrates a schematic cross-sectional view of a package structure 50′ according to some other embodiments of the present disclosure. The package structure 50′ is similar to the package structure 50, with the difference that in the package structure 50′, the die 10′ further includes a heat dissipation structure 8 and a barrier layer 6. The heat dissipation structure 8 is embedded in the substrate 2, and the barrier layer 6 is disposed between the heat dissipation structure 8 and the substrate 2 to space them apart from each other. In some embodiments, the heat dissipation structure 8 includes a material with a thermal conductivity greater than that of the substrate 2, so as to improve the thermal conductivity of the material of the die, thereby reducing the thermal resistance of the die 10. In some embodiments, the heat dissipation structure 8 includes a plurality of heat dissipation blocks arranged at intervals in the substrate 2, and some portions (for example, a first portion) of the substrate 2 are located laterally aside the heat dissipation structure 8 and are alternately arranged with the plurality of heat dissipation blocks, in a direction parallel to the main surface of the substrate; that is, the first portion of the substrate 2 includes a plurality of substrate material blocks, the plurality of substrate material blocks and the plurality of heat dissipation blocks are alternately arranged in a direction parallel to the main surface of the substrate, and each of the heat dissipation blocks is located between adjacent substrate material blocks. The substrate 2 further includes a body part located on a side of the plurality of substrate material blocks and heat dissipation blocks close to the device layer 5, and the heat dissipation structure may not be filled in the body part.

The enlarged view in FIG. 1B schematically illustrates an equivalent thermal resistance diagram of a plurality of heat dissipation blocks of the die 10, the substrate material blocks laterally aside the dissipation blocks and the body part of the substrate below them. In some embodiments, the heat dissipation of the die 10 is realized mainly through its substrate 2 and the heat dissipation structure 8 embedded in the substrate (i.e., the non-functional area). In some embodiments, it is assumed that the plurality of substrate material blocks and heat dissipation blocks located on the body part of the substrate 2 have substantially the same cross-sectional areas respectively in a direction perpendicular to the heat flux direction, the thermal resistance of each heat dissipation block is R₁, the thermal resistance of the body part of the substrate 2 is R₂, and the thermal resistance of each substrate material block laterally aside the heat dissipation block is R₃; given that the number of heat dissipation blocks is n and the number of substrate material blocks alternately arranged with the heat dissipation blocks is n+1, the formula (c) for calculating the thermal resistance R_{D} of the die 10 can be derived as follows:

$${R}_{D} = {R}_{2} + \frac{1}{\frac{n}{{R}_{1}} + \frac{n + 1}{{R}_{3}}} , \qquad ( c )$$

wherein the thermal resistance R_{D} of the part of the die including the above-mentioned heat dissipation structure and the substrate, the thermal resistance R₂ of the body part of the substrate 2, the thermal resistance R₁ of the heat dissipation block and the thermal resistance R₃ of the substrate material block are all thermal resistances thereof along the heat flux direction, and the unit is K/W.

According to the above formula (b), the following formula (d) can be derived. With the formula (d) being substituted into the formula (c), the formula (c) can be simplified as the following formula (e):

$${R}_{1} = \frac{{K}_{3} {R}_{3}}{{K}_{1}} \qquad ( d )$$

$${R}_{D} = {R}_{2} + \frac{{K}_{3} {R}_{3}}{{nK}_{1} + ( n + 1 ) {K}_{3}} = {R}_{2} + \frac{{R}_{3}}{( φ + 1 ) n + 1} . \qquad ( e )$$

In the above formula, K₁ is a thermal conductivity of a material of the heat dissipation structure, and K₃ is the thermal conductivity of the material of the substrate; φ is a ratio of K₁ to K₃, that is, φ=K₁/K₃.

According to the above formula, the thermal resistance R_{D} of the die is inversely proportional to the value of φ, that is, the greater the ratio of the thermal conductivity of the material of the heat dissipation structure to the thermal conductivity of the material of the substrate, the smaller the thermal resistance R_{D} of the die. For example, when the substrate 2 of the die is not filled with heat dissipation material, that is, when the material of the substrate still remains at the position where the heat dissipation structure 8 is located, φ=1; and when the substrate 2 of the die is filled with heat dissipation material and the thermal conductivity of the heat dissipation structure 8 is greater than that of the substrate 2, φ>1; according to formula (c), the thermal resistance of the die with φ>1 is smaller than the thermal resistance of the die with φ=1.

That is to say, by filling the substrate 2 with a material with a thermal conductivity greater than that of the material of the substrate as a heat dissipation structure, the thermal resistance of the die can be reduced, thereby improving the heat dissipation performance of the die. For example, when the material of the substrate 2 is silicon, the thermal conductivity of silicon is about 150 W/(m·K), and the material of the heat dissipation structure 8 may be a material with thermal conductivity greater than that of silicon. For example, the material of the heat dissipation structure 8 may include copper with a thermal conductivity of about 401 W/(m·K), silver with a thermal conductivity of about 429 W/(m·K), and other metal materials with high thermal conductivity, but the present disclosure is not limited thereto. The heat dissipation structure 8 may also include nonmetal materials or other types of materials, as long as the thermal conductivity of the material is greater than that of the material of the substrate.

In some embodiments, as illustrated in FIG. 1B and FIG. 1C, the plurality of heat dissipation blocks of the heat dissipation structure 8 are a plurality of heat dissipation pillars extending into the substrate 2 from a back surface of the substrate away from the device layer 5, and a sidewall and a bottom surface of each heat dissipation pillar are covered by the barrier layer 6 and surrounded by the substrate 2. In some embodiments, the plurality of heat dissipation pillars of the heat dissipation structure 8 may be formed by the following processes: patterning the substrate 2 by using a patterning process including photolithography and etching (for example, dry etching) to form a plurality of through holes in the substrate 2, and then forming a barrier layer and heat dissipation pillars to fill the through holes. In some embodiments, by increasing a filling ratio of the material of the heat dissipation structure in the substrate 2, the thermal resistance of the die can also be reduced and the heat dissipation performance of the die can be improved.

On the other hand, the thermal interface material layer 16 is disposed between the die 10 and the heat dissipation lid 30. For example, the thermal interface material layer 16 is attached to the back side of the die 10 away from the device layer 5. The thermal conductivity of air is about 0.0267 W/(m·K); while the thermal conductivity of the thermal interface material layer 16 is usually 3-12 W/(m·K). Therefore, during the heat dissipation of the die, the effect of air can be ignored, and the heat of the die is mainly conducted to the heat dissipation lid 30 through the thermal interface material layer 16, and then dissipated to the outside through the heat dissipation lid 30.

In some embodiments, according to the above formula (b), the thermal resistance of the die 10 is further related to a cross-sectional area (for example, a surface area of the back side) of the die in a direction perpendicular to the heat flux direction. In some embodiments, given that a material and a thickness of the thermal interface material layer 16 remain unchanged, a thermal resistance of the thermal interface material layer 16 is inversely proportional to a cross-sectional area of the thermal interface material layer in a direction perpendicular to the heat flux direction, while the cross-sectional area of the thermal interface material layer 16 corresponds to (for example, is substantially the same as) the surface area of the back side of the die 10. In some embodiments, the above-mentioned cross-sectional area of the thermal interface material layer 16 is substantially equal to a contact area between the die 10 and the thermal interface material layer 16 and a contact area between the thermal interface material layer 16 and the heat dissipation lid 30, that is, substantially equal to a heat dissipation area of the back side of the die. Therefore, by increasing the heat dissipation area of the back side of the die, it can also be beneficial to the heat dissipation of the die, thereby improving the heat dissipation performance of the die and the package structure and reducing the risk of thermal damage or life shortening of the die.

In various embodiments of the present disclosure, a package structure and a manufacturing method thereof are provided to improve the heat dissipation performance of a die and the package structure. For example, in the die of the package structure, at least one of a heat dissipation filling structure and a substrate recess is provided in the substrate; the heat dissipation filling structure can be formed by forming a trench in the substrate by using a cutting process and then filling the trench with a heat dissipation material with high thermal conductivity, so that the thermal resistance of the die can be reduced and the heat dissipation performance of the die can be improved by increasing the thermal conductivity of the material of the die; moreover, a trench with a large size can be formed by using the cutting process, so that a content of heat dissipation materials in the die can be increased, thus greatly reducing the thermal resistance of the die and improving the heat dissipation performance of the die. On the other hand, the substrate recess is configured to increase the heat dissipation area of the die; for example, the substrate recess is disposed at a side close to the thermal interface material layer, and the thermal interface material layer extends into the substrate recess; the thermal dissipation component is configured to have a heat dissipation protrusion corresponding to the substrate recess, and the heat dissipation protrusion also extends into the substrate recess; in this way, by increasing a surface area of the die at a side close to the thermal interface material layer, the contact area between the die and the thermal interface material layer and the contact area between the thermal dissipation component and the thermal interface material layer are increased; that is, the heat dissipation area of the die is increased, and hence the heat dissipation performance of the die is improved.

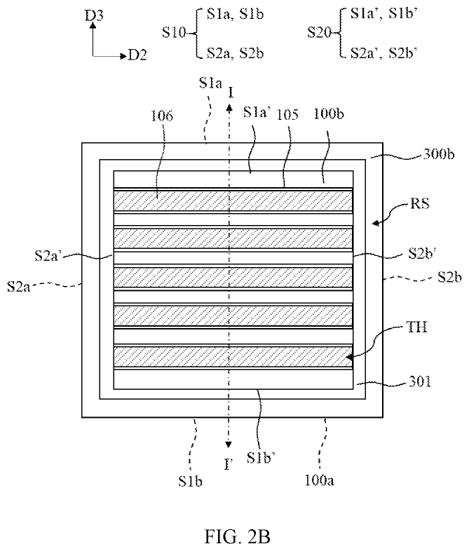

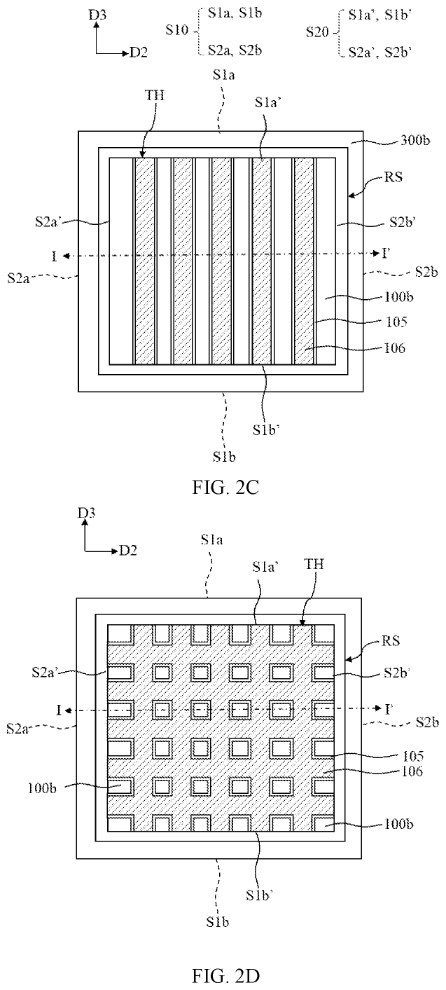

FIG. 2A illustrates a schematic cross-sectional view of a package structure according to some embodiments of the present disclosure; FIG. 2B to FIG. 2D illustrate plan views of the package structure illustrated in FIG. 2A according to some embodiments of the present disclosure, wherein FIG. 2A is taken along the line I-I′ of any one of FIG. 2B to 2D. For simplicity of the drawing, FIG. 2B to FIG. 2D only illustrate the die, the thermal interface material layer and the heat dissipation protrusion of the thermal dissipation component in the package structure. In this embodiment, by filling the substrate of the die with a material having high thermal conductivity as a heat dissipation filling structure and by further increasing the heat dissipation area of the die, the thermal resistance of the die is reduced, thereby improving the heat dissipation performance of the die and the package structure.

Referring to FIG. 2A, in some embodiments, the package structure 500a includes a die 120a, a thermal dissipation component 300 and a package substrate 200. The die 120a is mounted on and electrically connected to the package substrate 200. In some embodiments, conductive connectors 220 are disposed on the package substrate 200 at a side away from the die 120a, and the conductive connector 220 is electrically connected to the die 120a through the package substrate 200, and the package structure 500a can be further connected to other package components or electronic components through the conductive connectors 220.

In some embodiments, the thermal dissipation component 300 is disposed on the package substrate 200 and may cover and surround the die 120a; the thermal dissipation component 300 is configured to dissipate the heat of the die 120a (for example, the heat generated during operation) away from the die 120a. In some embodiments, the thermal dissipation component 300 is attached to the package substrate 200 through an adhesive layer 302, and is attached to the die 120a through a thermal interface material layer 301. During the heat dissipation, the heat of the die 120a is conducted from the die 120a to the thermal interface material layer 301, and then conducted to the thermal dissipation component 300 through the thermal interface material layer 301, and further dissipated to the outside through the thermal dissipation component 300.

In some embodiments, the die 120a includes a substrate 100, a device layer 101, conductive bumps 102 and a heat dissipation filling structure (or referred to as a thermal dissipation filling structure) 106. The substrate 100 may be a semiconductor substrate, such as a silicon substrate, but may also include other types of semiconductor materials and/or other materials. The device layer 101 is disposed on a side of the substrate 100 in a direction perpendicular to the main surface of the die, and may also be referred to as an active layer or a functional area of the die 120a, while the substrate 100 may also be referred to as a non-functional area of the die 120a. In other words, the substrate 100 has a front side and a back side opposite to each other in a direction (for example, a direction D1) perpendicular to the main surface of the die, and the device layer 101 is disposed at the front side of the substrate 100. In some embodiments, the direction D1 may be a vertical direction and may be referred to as a first direction. In some embodiments, the side of the die 120a close to the device layer and the front side of the substrate is referred to as the front side of the die, and the side of the die 120a close to or including the back side of the substrate is referred to as the back side of the die.

The conductive bump 102 is disposed on a side of the device layer 101 away from the substrate 100, and the conductive bump 102 is closer to the front side of the substrate relative to the back side of the substrate 100. That is to say, the die 120a has a front side FS and a back side BS opposite to each other in a direction (e.g., direction D1) perpendicular to its main surface or the main surface of the substrate 100 (e.g., the surface at a side close to the device layer 101); the front side FS is the side close to the device layer 101 and provided with the conductive bumps 102, and may also be referred to as an active side of the die 120a; the back side BS is the side close to or including the back side of the substrate 100 and/or the heat dissipation filling structure. The surface of the die 120a at the front side FS may also be referred to as a front surface of the die 120a; and the surface of the die 120a at the back side BS may also be referred to as a back surface of the die 120a. It should be understood that the front side of the die 120a includes its front surface, and also includes a part close to the front surface; the back side of the die 120a includes its back surface, and also includes a part close to the back surface.

In some embodiments, the heat dissipation filling structure 106 is configured to reduce the thermal resistance of the die and improve the heat dissipation performance of the die 120a. The heat dissipation filling structure 106 may be located at the back side of the die 120a and embedded in the substrate 100. The heat dissipation filling structure 106 may have a part exposed at a sidewall of the substrate 100. The thermal conductivity of the material of the heat dissipation filling structure 106 is greater than the thermal conductivity of the material of the substrate 100. In some embodiments, a barrier layer 105 is disposed between the heat dissipation filling structure 106 and the substrate 100 to separate the heat dissipation filling structure 106 and the substrate 100 from each other. For example, the barrier layer 105 may surround opposite sidewalls of the heat dissipation filling structure 106 and a surface (i.e., the bottom surface illustrated in the figure) connecting side edges of the opposite sidewalls of the heat dissipation filling structure 106.

In some embodiments, the heat dissipation filling structure 106 includes a metal material such as copper, silver or the like; the barrier layer 105 can be configured to prevent the metal materials of the heat dissipation filling structure 106 from diffusing to the substrate 100, and the barrier layer 105 can be further configured to electrically isolate the heat dissipation filling structure 106 from the substrate 100. The barrier layer 105 may include a metal material such as titanium, or an insulating material such as silicon oxide, silicon nitride or the like. In some embodiments, the thermal conductivity of the barrier layer 105 may also be greater than that of the substrate 100, but the present disclosure is not limited thereto. In some other embodiments, the heat dissipation filling structure 106 includes a nonmetal material with high thermal conductivity, as such, the barrier layer 105 can be optionally disposed between the heat dissipation filling structure 106 and the substrate 100, and can be omitted, for example.

In some embodiments, the substrate 100 has one or more trenches TH. The trench TH is configured to be filled with the heat dissipation filling structure 106 having high thermal conductivity, thereby reducing the thermal resistance of the die and improving the heat dissipation performance of the die. In some embodiments, the substrate 100 further has a recess (or referred to as substrate recess) RS, which is recessed from the back side of the substrate 100 towards the device layer 101, and parts of the thermal interface material layer 301 and the thermal dissipation component 300 extend into the recess RS; in this way, through disposing the recess RS, a cross-sectional area of the back side of the die is increased, thereby increasing the contact area between the thermal interface material layer 301 and the die 120a and the contact area between the thermal dissipation component 300 and the thermal interface material layer 301, that is, the heat dissipation area of the die 120a is increased, thereby further improving the heat dissipation performance of the die 120a.

In some embodiments, the trench TH may be located in a middle part of the substrate 100, and the recess RS may be located at an edge of the substrate 100. For example, referring to FIG. 2A to 2C, in some embodiments, a plurality of trenches TH of the substrate 100 extend in a direction parallel to the main surface of the substrate 100, for example, may extend in a direction D2 or a direction D3. The direction D2 and the direction D3 are, for example, horizontal directions. The direction D2 and the direction D3 may intersect with each other, may be perpendicular to each other, for example, and may be referred to as a second direction and a third direction, respectively, or vice versa. The plurality of trenches TH may be spaced apart from each other. In some other embodiments, as illustrated in FIG. 2D, the trenches TH may be in a grid shape, and include a part extending in the direction D2 and a part extending in the direction D3 which intersect with each other. The recess RS may be located at the edge of the die 120a and is, for example, ring-shaped, and a plurality of trenches TH and the heat dissipation filling structure 106 filled therein may be located in an area surrounded by the recess RS. However, the present disclosure is not limited thereto.

In other words, the substrate 100 includes a body part 100a and a protruding part 100b, the body part 100a is located at a position close to the device layer 101, and the protruding part 100b is located on a side of the body part 100a away from the device layer 101. In some embodiments, the trench TH and the recess RS are located on the body part 100a and laterally aside the protruding part 100b; for example, the trench TH is located between adjacent protruding parts 100b, and the recess RS may be located outside the outermost sidewall of the protruding part 100b close to the edge of the die, but the present disclosure is not limited thereto.

The heat dissipation filling structure 106 is filled in the trench TH of the substrate 100, that is, embedded in the substrate 100. In some embodiments, the heat dissipation filling structure 106 is located on a side of the body part 100a of the substrate 100 away from the device layer 101, and is disposed between the protruding parts 100b. That is to say, the heat dissipation filling structure 106 overlaps with the protruding part 100b of the substrate 100 in a direction parallel to the main surface of the substrate 100 (for example, the direction D2 and/or the direction D3).

For example, as illustrated in FIG. 2B, the heat dissipation filling structure 106 includes a plurality of heat dissipation strips, which extend parallel to each other in the direction D2 and are arranged in the direction D3; the barrier layer is disposed between each heat dissipation strip and the substrate 100; and each heat dissipation strip of the heat dissipation filling structure 106 and the barrier layer extend to pass through the substrate 100 in the direction D2, and opposite sidewalls of the heat dissipation filling structure 106 and the barrier layer 105 in the direction D2 are exposed by the substrate 100, for example, exposed at a sidewall of the substrate located between the front side and the back side of the substrate; that is to say, the part of the heat dissipation filling structure 106 exposed at the sidewall of the substrate may include opposite sidewalls thereof in the direction D2. A plurality of protruding parts 100b of the substrate 100 also extend in the direction D2 and are arranged in the direction D3; the plurality of heat dissipation strips are each positioned between adjacent protruding parts 100b of the substrate. That is to say, the plurality of protruding parts 100b of the substrate 100 and the plurality of heat dissipation strips of the heat dissipation filling structure 106 are alternately arranged with each other in the direction D3. In some embodiments, the heat dissipation filling structure 106, the barrier layer 105 and the protruding parts 100b of the substrate 100 may have sidewalls substantially aligned with each other in the direction D3, but the present disclosure is not limited thereto.

In some embodiments, an extension direction and an arrangement direction of the heat dissipation filling structure and the protrusions of the substrate can be adjusted. For example, as illustrated in FIG. 2C, the plurality of heat dissipation strips of the heat dissipation filling structure 106 extend parallel to each other in the direction D3 and are arranged in the direction D2; the barrier layer is arranged between each heat dissipation strip and the substrate 100; each heat dissipation strip of the heat dissipation filling structure 106 and the barrier layer extend to pass through the substrate 100 in the direction D3, and opposite sidewalls of the heat dissipation filling structure 106 and the barrier layer 105 in the direction D3 are exposed by the substrate 100; the plurality of protruding parts 100b of the substrate 100 also extend in the direction D3 and are arranged in the direction D2; the plurality of heat dissipation strips are each positioned between adjacent protruding parts 100b of the substrate. That is to say, the plurality of protruding parts 100b of the substrate 100 and the plurality of heat dissipation strips of the heat dissipation filling structure 106 are alternately arranged with each other in the direction D2. In some embodiments, the heat dissipation filling structure 106, the barrier layer 105 and the protruding parts 100b of the substrate 100 may have sidewalls substantially aligned with each other in the direction D2, but the present disclosure is not limited thereto.

In the embodiment illustrated in FIGS. 2B and 2C, the plurality of protruding parts 100b are spaced apart from each other by the heat dissipation filling structure 106 arranged between the protruding parts 100b in a direction parallel to the main surface of the substrate (for example, the horizontal direction illustrated in the figure), and the plurality of heat dissipation strips of the heat dissipation filling structure 106 are also spaced apart from each other by the protruding parts 100b between adjacent heat dissipation strips. However, embodiments of the present disclosure are not limited thereto.

For example, as illustrated in FIG. 2D, in some other embodiments, the heat dissipation filling structure 106 is approximately in the shape of grid, and includes a plurality of parts extending in the direction D2 and a plurality of parts extending in the direction D3 which intersect with each other. The plurality of protruding parts 100b are located in gaps between the respective parts of the grid-shaped heat dissipation filling structure 106, and are laterally spaced apart from each other by the heat dissipation filling structure 106 located therebetween. It should be understood that the shape of the heat dissipation filling structure 106 illustrated in the figure is only for an illustration, and the present disclosure is not limited thereto, and the heat dissipation filling structure 106 may have any suitable shape.

In some embodiments, as illustrated in FIG. 2B to 2D, when viewed in a plan view, the substrate recess RS is arranged at edges of the die and the substrate, and the protruding parts 100b of the substrate 100 and the heat dissipation filling structure 106 are located in a region surrounded by the substrate recess RS. However, the present disclosure is not limited thereto.

In some embodiments, the die 120a has a first back surface T1 and a second back surface T2 at back side BS thereof (e.g., the back side of the substrate). The second back surface T2 is further away from the device layer 101 than the first back surface T1 to the device layer 101. For example, in a direction (for example, the direction D1) perpendicular to the main surface of the substrate 100, a distance between the first back surface T1 of the substrate 100 and the device layer 101 is smaller than a distance between the second back surface T2 of the substrate 100 and the device layer 101. In some embodiments, the first back surface T1 is the surface of the body part 100a exposed by the recess RS, and the second back surface T2 may include surfaces of the protruding part 100b of the substrate, the heat dissipation filling structure 106 and/or the barrier layer 105 that are located at the back side BS of the die and close to the thermal interface material layer (i.e., the top surface illustrated in the figure). In some embodiments, the surface of the substrate 100 close to the device layer 101 is referred to as the front surface or the main surface of the substrate 100; that is to say, in a direction perpendicular to the main surface of the substrate 100, a distance between the first back surface T1 of the substrate 100 and the front surface thereof is smaller than a distance between the second back surface T2 of the substrate 100 and the front surface thereof.

Referring to FIG. 2A to FIG. 2D, in some embodiments, the die 120a has a first sidewall S10 and a second sidewall S20 which are laterally offset from each other in a direction parallel to the main surface of the die 120a (e.g., direction D2 and/or direction D3), and the second sidewall S20 is closer to the center of the die 120a than the first sidewall S10 to the center of the die 120a, while the first sidewall S10 is closer to the edge of the package substrate 200 relative to the second sidewall S20. For example, the first sidewall S10 includes a sidewall of the body part 100a of the substrate 100 and a sidewall of the device layer 101, and the sidewall of the body part 100a and the sidewall of the device layer 101 may be substantially aligned with each other in the direction D1; the second sidewall S20 may include sidewalls of the protruding part 100b of the substrate 100, the heat dissipation filling structure 106 and/or the barrier layer 105 that are close to the edge of the substrate, and may be exposed by the substrate recess RS and in contact with the thermal interface material layer 301. In some embodiments, the recess RS is recessed from the back surface T2 of the back side of the die 120a towards the device layer 101, and may have a boundary defined by the back surface T1 and the sidewall S20 of the die 120a. The body part 100a of the substrate 100 laterally extends beyond the second sidewall S20 of the die in a direction (for example, direction D2/D3) parallel to the main surface of the substrate.

For example, referring to FIG. 2A to FIG. 2D, the first sidewall S10 and the second sidewall S20 of the die 120a may each include four side edges (or referred to as sub-sidewalls), and the corresponding side edges of the first sidewall S10 and the second sidewall S20 may extend parallel to each other. For example, the first sidewall S10 includes four side edges S1a, S1b, S2a and S2b, and the second sidewall S20 includes four side edges S1a′, S1b′, S2a′ and S2b′. In some examples, as illustrated in FIG. 2B, among the four side edges of the second sidewall S20 of the die 120a, the side edges S1a′ and S1b′ that extend in the direction D2 and are opposite to each other in the direction D3 are the side edges of the protruding parts 100b close to the edge of the substrate or the die, while the side edges S2a′ and S2b′ that extend in the direction D3 and are opposite to each other in the direction D2 may each include side edges of the protruding part 100b, the heat dissipation filling structure 106 and the barrier layer 105 which are close to the edge of the substrate or the die, wherein these side edges of the protruding part 100b, the heat dissipation filling structure 106 and the barrier layer 105 may be substantially aligned with each other in the direction D3. The side edges of the first sidewall S10 of the die 120a are located between the front surface and the back surface T1 of the die, and side edges of the second sidewall S20 of the die 120a are located between the back surface T1 and the back surface T2 of the die; the back surfaces T1 and T2 of the die extend in a direction parallel to a main surface of the die (for example, the directions D2, D3 or other horizontal directions), and the surfaces where the first sidewall S10 and the second sidewall S20 are located extend in a direction perpendicular to the main surface of the die (for example, the vertical direction such as the direction D1) and also extend in a direction parallel to the main surface of the die (for example, the directions D2, D3 or other horizontal directions). It should be understood that, since a heat dissipation protrusion 300b is illustrated in the plan views of FIG. 2B to 2D, the body part 100a of the substrate located below the heat dissipation protrusion may be invisible in these plan views, with the result that the respective side edges S1a, S1b, S2a, S2b of the body part 100a in the figures are illustrated by dotted lines.

In some examples, as illustrated in FIG. 2C, among the four side edges of the second sidewall S20 of the substrate 100, the side edges S2a′ and S2b′ that extend in the direction D3 and are opposite to each other in the direction D2 are the side edges of the protruding parts 100b close to the edge of the die; while the side edges S1a′ and S1b′ that extend in the direction D2 and are opposite to each other in the direction D3 include the side edges of the protruding part 100b, the heat dissipation filling structure 106 and the barrier layer 105 close to the edge of the die, and these side edges of the protruding part 100b, the heat dissipation filling structure 106 and the barrier layer 105 may be substantially aligned with each other in the direction D2. In some other examples, as illustrated in FIG. 2D, each side edge of the second sidewall S20 of the substrate 100 includes side edges of the protruding part 100b, the heat dissipation filling structure 106 and the barrier layer 105 close to the edge of the die.

Still referring to FIG. 2A to FIG. 2D, in some embodiments, the thermal interface material layer 301 is attached to the back side BS of the die 120a, and extends along the second back surface T2 of the die 120a and is filled in the recess RS. That is to say, the thermal interface material layer 301 is located on the body part 100a and the protruding part 100b of the substrate 100, covers the first back surface T1 and the second back surface T2 of the die 120a, and surrounds the second sidewall S20 of the die 120a; the thermal interface material layer 301 is in contact (e.g., in direct contact) with the second back surface T2, the second sidewall S20 and the first back surface T1 of the die 120a. In some embodiments, a contact area between the thermal interface material layer 301 and the die 120a is substantially equal to a sum of surface areas of the first back surface T1, the second back surface T2 and the second sidewall S20 of the die 120a. In other words, the thermal interface material layer 301 includes a first portion and a second portion, wherein the first portion is located on and in contact with the back surface T2 of the die 120a; the second portion extends into the substrate recess RS to be in contact with the back surface T1 and the sidewall S20 of the die 120a; the first portion and the second portion may also be referred to as a thermal interface body part and a thermal interface extension part, respectively. In some embodiments, the outermost sidewall of the thermal interface material layer 301 is slightly laterally offset from the sidewall S10 of the substrate in a direction parallel to the main surface of the substrate, but the present disclosure is not limited thereto. In some other embodiments, the thermal interface material layer 301 may have a sidewall substantially aligned with the sidewall S10 of the substrate in a direction (e.g., direction D1) perpendicular to the main surface of the substrate. The thermal interface material layer 301 may be, for example, a conformal layer, but the present disclosure is not limited thereto.

In some embodiments, the thermal dissipation component 300 may be a heat dissipation lid and made of a material with high thermal conductivity, and the thermal conductivity of the thermal dissipation component 300 may be greater than that of the substrate 100 of the die. For example, the thermal dissipation component 300 may include a metal material such as copper, gold, silver, steel, or the like.

In some embodiments, the thermal dissipation component 300 has a heat dissipation body part 300a and a heat dissipation protrusion 300b connected with each other. The heat dissipation body part 300a and the heat dissipation protrusion 300b may be integrally formed, but the present disclosure is not limited thereto. The thermal dissipation component 300 is located on a side of the thermal interface material layer 301 away from the die 120a, and surrounds the die 120a in a direction parallel to the main surface of the substrate 100. Specifically, the heat dissipation body part 300a of the thermal dissipation component 300 is located on the back surface T2 of the die 120a and the thermal interface body part of the thermal interface material layer 301; and the heat dissipation protrusion 300b is protruded from the heat dissipation body part 300a towards the die 120a (for example, towards the first back surface of the die) and the package substrate 200 in a direction (for example, the direction D1) perpendicular to the main surface of the substrate, and is protruded from the surface of the heat dissipation body part 300a facing the second back surface T2 of the die 120a and in contact with the thermal interface body part. The heat dissipation protrusion 300b extends into the recess RS of the die 120a to be in contact (e.g., direct contact) with the second part of the thermal interface material layer 301 (i.e., the thermal interface extension part) located in the recess RS. In some embodiments, the heat dissipation protrusion 300b has a shape corresponding to the recess RS of the substrate 100, so that the heat dissipation protrusion 300b can be correspondingly disposed in the recess RS of the substrate 100. For example, as illustrated in FIG. 2B to FIG. 2D, the heat dissipation protrusion 300b may also be substantially ring-shaped, and the recess RS of the substrate 100 may be substantially engaged with the heat dissipation protrusion 300b. In some embodiments, the heat dissipation protrusion 300b overlaps with the protruding part 100b of the substrate 100, the heat dissipation filling structure 106, the barrier layer 105 and the thermal interface material layer 301 in a direction (e.g., direction D2, D3) parallel to the main surface of the die 120a, and is in contact with a sidewall and a top surface of the thermal interface material layer 301, and may laterally surround at least parts of the thermal interface material layer 301 and the protruding part 100b of the substrate 100 and the heat dissipation filling structure 106.

In some embodiments, a first part (i.e., the thermal interface body part) of the thermal interface material layer 301 is sandwiched between the back surface T2 of the die 120a and the heat dissipation body part 300a, and a second part (i.e., the thermal interface extension part) of the thermal interface material layer 301 is sandwiched between the sidewall S20 of the die 120a and the heat dissipation protrusion 300b and between the back surface T1 of the die 120a and the heat dissipation protrusion 300b. The thermal interface material layer 301 has a first bottom surface, an inner sidewall and a second bottom surface which are respectively in contact with the first back surface T1, the second sidewall S20 and the second back surface T2 of the die 120a; the first bottom surface and the second bottom surface of the thermal interface material layer 301 are located at different level heights relative to the main surface of the package substrate 200 or the main surface of the substrate 100 which is in contact with the device layer 101, that is, the first bottom surface of the thermal interface material layer 301 is lower than the second bottom surface thereof and is closer to the front side of the substrate and the device layer.

The thermal interface material layer 301 has a first top surface, a first outer sidewall and a second top surface opposite to the first bottom surface, the inner sidewall and the second bottom surface thereof, respectively; the second top surface of the thermal interface material layer 301 is in contact with the heat dissipation body part 300a, the first outer sidewall of the thermal interface material layer 301 is in contact with an inner sidewall of the heat dissipation protrusion 300b, and the first top surface of the thermal interface material layer 301 is in contact with a bottom surface of the heat dissipation protrusion 300b. A contact area between the thermal interface material layer 301 and the thermal dissipation component 300 is substantially equal to an area of the surface of the thermal interface material layer 301 facing the thermal dissipation component 300, that is, a sum of surface areas of the first top surface, the first outer sidewall and the second top surface of the thermal interface material layer 301. The bottom surface of the heat dissipation protrusion 300b faces the back surface T1 of the die 120a, and is located at a level height between the back surface T1 and the back surface T2 of the die 120a in a direction perpendicular to the main surface of the die. In some embodiments, an outer sidewall (i.e., the sidewall opposite to the inner sidewall thereof) of the heat dissipation protrusion 300b, the second outer sidewall (i.e., the outermost sidewall) of the thermal interface material layer 301, and the sidewall S10 of the die 120a may or may not be aligned with each other in a direction (e.g., the direction D1) perpendicular to the main surface of the die 120a.

In some embodiments, the thermal interface extension part of the thermal interface material layer 301 located in the recess RS is approximately L-shaped or the like, and has a horizontal extension portion extending along the back surface T1 of the body part 100a of the substrate and a vertical extension portion extending along the second sidewall S20 of the die 120a; the horizontal extension portion extends approximately in a direction parallel to the main surface of the die (for example, directions D2 and D3), and the vertical extension portion extends approximately in a direction perpendicular to the main surface of the die (for example, direction D1). The heat dissipation protrusion 300b is located on the horizontal extension portion of the thermal interface extension part, and may laterally surround the vertical extension portion of the thermal interface extension part, the thermal interface body part and a part of the die 120a that is in contact with these parts of the thermal interface material layer in a direction parallel to the main surface of the die. For example, the vertical extension portion of the thermal interface extension part, the thermal interface body part, and at least parts of the substrate protruding part 100b, the heat dissipation filling structure 106 and the barrier layer 105 of the die 120a are located in a space surrounded and delimited by the inner sidewall of the heat dissipation protrusion 300b.

In some embodiments, the heat dissipation body part 300a of the thermal dissipation component 300 may include a horizontal body part BP1, a landing part BP2, and a connection part BP3. The horizontal body part BP1 is located on the thermal interface material layer 301 and connected with the heat dissipation protrusion 300b, and can extend substantially in a direction parallel to the main surface of the die (for example, directions D2 and D3). The landing part BP2 is located on the package substrate 200 and attached to the package substrate 200 through an adhesive layer 302. The connection part BP3 is located between the horizontal body part BP1 and the landing part BP2, so as to connect the horizontal body part BP1 and the landing part BP2 to each other. In this embodiment, the horizontal body part BP1 and the landing part BP2 are located at different level heights relative to the main surface of the package substrate 200, and the connection part BP3 may be inclined, for example, but the present disclosure is not limited thereto. The heat dissipation body part 300a may have any other suitable shapes.

In some embodiments, the heat dissipation protrusion 300b is laterally surrounded by a portion of the heat dissipation body part 300a (for example, the connection part BP3) in a direction parallel to the main surface of the die, and is laterally spaced apart from this portion of the heat dissipation body part 300a, but the present disclosure is not limited thereto.

In some embodiments, the heat of the die 120a is dissipated in a direction substantially perpendicular to the main surface of the die (for example, direction D1), and a part of the heat may also be dissipated in a direction substantially parallel to the main surface of the die (for example, directions D2 and D3). For example, most of the heat of the die 120a is conducted from the back surfaces T1 and T2 at the back side of the die 120a to the thermal interface material layer 301 along the direction D1, and further conducted to the thermal dissipation component 300 through the thermal interface material layer 301, and then dissipated to the outside through the thermal dissipation component 300; that is to say, the heat flux direction of this part of heat is substantially perpendicular to the main surface of the die; a part of the heat of the die 120a can also be conducted from the sidewall S20 of the die 120a to the thermal interface material layer 301 along a direction substantially parallel to the main surface of the die (for example, directions D2 and D3), and further conducted to the heat dissipation protrusion 300b of the thermal dissipation component 300 through the thermal interface material layer 301, that is, the heat flux direction of this part of the heat is substantially parallel to the main surface of the die.

In this embodiment, since the substrate 100 has a recess RS, the thermal interface material layer 301 is filled in the recess RS, and the thermal dissipation component 300 has a corresponding heat dissipation protrusion 300b extending into the recess RS, the heat dissipation area of the die 120a can be increased, and the heat dissipation performance of the die 120a can be further improved. Specifically, a surface area of the back side of the die 120a in a direction perpendicular to the heat flux direction is substantially equal to a sum of surface areas of the back surface T1, the back surface T2 and the sidewall S20 of the die 120a; and a contact area between the die 120a and the thermal interface material layer 301 is substantially equal to (or slightly smaller than) the sum of the surface areas of the back surface T1, the back surface T2 and the sidewall S20 of the die 120a; accordingly, a contact area between the thermal dissipation component 300 and the thermal interface material layer 301 is substantially equal to a sum of surface areas of the corresponding top surfaces and outer sidewall of the thermal interface material layer 301. In this embodiment, a surface area of the back side of the die 120a (i.e., a sum of surface areas of the back surfaces T1 and T2 and the sidewall S20) is greater than an area of an orthographic projection of the die 120a (or its substrate 100) on the main surface of the die or the package substrate in a direction perpendicular to the main surface of the die (e.g., direction D1); accordingly, a contact area between the die 120a and the thermal interface material layer 301 and a contact area between the thermal interface material layer 301 and the thermal dissipation component 300 are both greater than the area of the orthographic projection of the die 120a (or its substrate 100) on the main surface of the die or the package substrate in a direction perpendicular to the main surface of the die.

Compared with the package structure illustrated in FIG. 1A to 1C, in the package structure 500a of this embodiment, the proportion of the heat dissipation filling structure 106 with greater thermal conductivity in the substrate 100 is increased, thereby further reducing the thermal resistance of the die 120a and improving the heat dissipation performance of the die. On the other hand, through disposing the recess RS in the substrate 100, the surface area of the back side of the die 120a (i.e., the cross-sectional area in a direction perpendicular to the heat flux direction) is increased; furthermore, the thermal interface material layer 301 and the thermal dissipation component 300 extend into the recess RS, so that the contact area between the die 120a and the thermal interface material layer 301 and the contact area between the thermal interface material layer 301 and the thermal dissipation component 300 are both increased, that is, the heat dissipation area of the die 120a is increased, thereby further reducing the thermal resistance of the die 120a and improving the heat dissipation performance of the device.

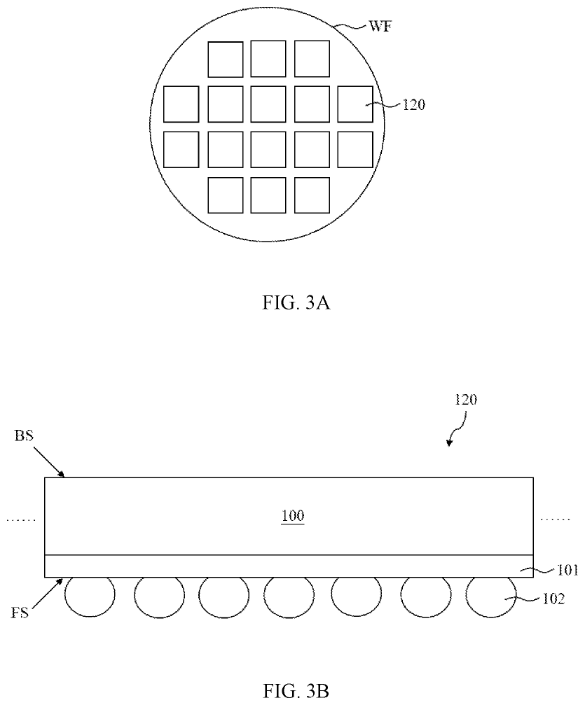

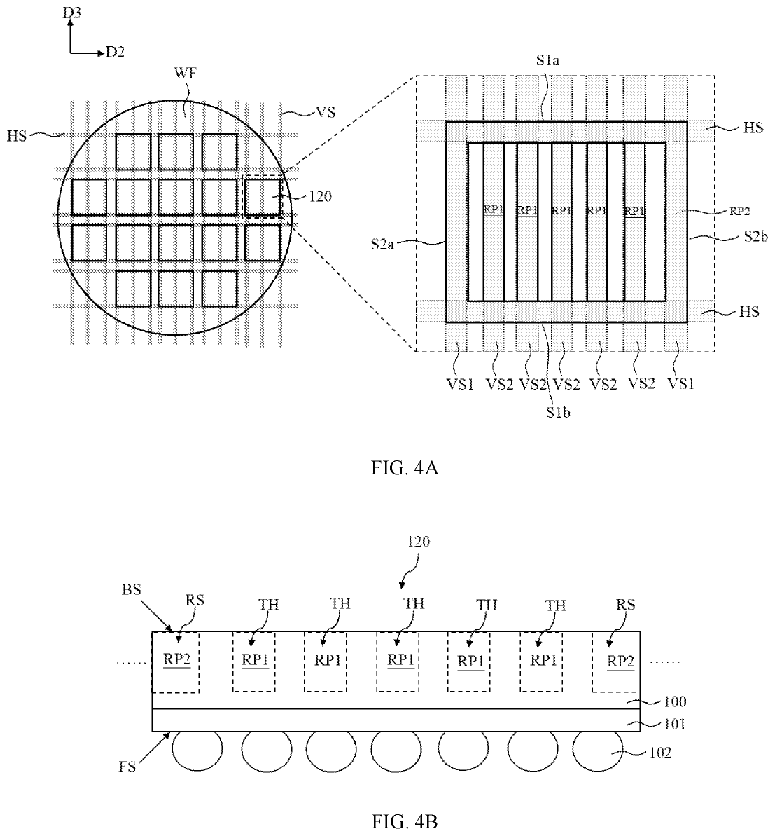

FIG. 3A and FIG. 3B to FIG. 11 are schematic top views and cross-sectional views illustrating a method of forming a package structure according to some embodiments of the present disclosure, wherein FIG. 3A, FIG. 3B to FIG. 7A and FIG. 7B are schematic top views and cross-sectional views illustrating a method of forming a die in a package structure according to some embodiments of the present disclosure.

Referring to FIG. 3A and FIG. 3B, in some embodiments, a wafer WF including a plurality of dies 120 is provided; for example, the plurality of dies 120 may be arranged in an array and spaced apart from each other. For example, the plurality of dies 120 are spaced apart from each other by a scribe region located therebetween. The scribe region is a region along which a wafer dicing process will be performed subsequently to cut through the wafer and separate the plurality of dies 120, and the scribe region may also be referred to as a scribe line. In some embodiments, the die 120 may also be referred to as a chip. It should be noted that FIG. 3B to FIG. 7B only illustrate schematic cross-sectional views of one die 120 in the wafer WF in various steps of a manufacturing process, and ellipsis are illustrated at both sides of the die 120 in FIG. 3B to 6B to indicate that there are other dies 120 included in the same wafer WF around the illustrated die 120; and it should be understood that the respective dies 120 in the wafer WF are subjected to substantially the same manufacturing process and has substantially the same cross-sectional structures in various steps of the manufacturing process.

In some embodiments, the die 120 includes a substrate 100, a device layer 101, and conductive bumps 102. In some embodiments, the substrate 100 is a semiconductor substrate, such as a silicon substrate, but the present disclosure is not limited thereto. The substrate 100 may also include other semiconductor materials such as germanium, silicon germanium, gallium arsenide, or the like. The substrate 100 may be an undoped bulk semiconductor substrate, or may be a doped semiconductor substrate doped with dopants such as phosphorus or arsenic. In addition, the substrate 100 may also be silicon-on-insulator (SOI) substrate, or the like.

The device layer 101 is disposed on a side of the substrate 100, and may include an integrated circuit device and an interconnection structure. For example, the device layer 101 may include active devices such as transistors and passive devices such as capacitors, resistors, or the like; the interconnection structure may include conductive lines and/or conductive vias which are connected to each other and connected to a plurality of devices so as to form a functional circuit. In some embodiments, the device layer 101 may also be referred to as an active layer or a functional area of the die 120, and the substrate 100 may also be referred to as a non-functional area of the die 120.

A plurality of conductive bumps 102 are located on a side of the device layer 101 away from the substrate 100, and may be electrically connected to the interconnection structure and a plurality of devices in the device layer 101, and serve as conductive terminals of the die 120 for external connection of the die 120. In some embodiments, the plurality of conductive bumps 102 may include solder balls and may be formed on the device layer 101 through a bumping process.

In some embodiments, the die 120 has a front side FS and a back side BS opposite to each other in a direction perpendicular to the main surface thereof. The front side FS is located at a side of the device layer 101 away from the substrate 101, and may also be referred to as an active side of the die 120; the back side BS is a side of the substrate 100 opposite to the front side FS of the die. Correspondingly, the side where the front sides FS of a plurality of dies 120 are located is a front side of the wafer WF, and the side where the back sides BS of the plurality of dies 120 are located is a back side of the wafer WF.

Referring to FIG. 4A and FIG. 4B, in some embodiments, a removal process is performed on the substrate 100 of the die 120 from the back side of the wafer WF, that is, the back side BS of the die 120, so as to remove parts RP1 and RP2 of the substrate 100 and form one or more trenches TH and a recess RS in the substrate 100. For example, a part RP1 of the substrate 100 is a middle part thereof away from the edge of the die, and a part RP2 is an edge part thereof close to the edge of the die. The process of removing the part RP1 of the substrate 100 to form a trench TH may also be referred to as a trenching process, and the process of removing the part RP2 of the substrate 100 to form a recess RS may also be referred to as a trimming process.

In some embodiments, a cutting process may be performed to partially cut the plurality of dies 120 of the wafer WF along a predetermined cutting path, so as to remove parts RP1 and RP2 of the die 120. The cutting process may also be referred to as a first cutting process, and may include a die saw process. For example, the cutting process may include a mechanical saw process for cutting with a saw blade or the like, a laser cutting process, other types of cutting processes, or combinations thereof.

FIG. 4A schematically illustrates the cutting path of the cutting process and an enlarged view of the cutting path for one of the dies 120.

For example, in the cutting process, the plurality of dies 120 of the wafer WF are cut along a plurality of cutting paths HS and a plurality of cutting paths VS. The plurality of cutting paths HS and the plurality of cutting paths VS extend in a direction parallel to a main surface of the wafer WF, respectively; the plurality of cutting paths HS may extend in a direction D2, for example, while the plurality of cutting paths VS extend in a direction D3. The direction D2 and the direction D3 intersect with each other and are, for example, perpendicular to each other. That is to say, the cutting path HS and the cutting path VS may intersect with each other, and may be perpendicular to each other, for example. However, the present disclosure is not limited thereto. In some embodiments, the path of the cutting apparatus can be programmed according to process requirements of products, so that the cutting apparatus can perform the cutting process according to a predetermined cutting path.

In some embodiments, the die 120 has side edges S1a and S1b that are opposite to each other in the direction D3 and extend in parallel to each other in the direction D2, and side edges S2a and S2b that are opposite to each other in the direction D2 and extend in parallel to each other in the direction D3; and the die 120 has edge parts RP2 close to the respective side edges. The edge part RP2 is, for example, ring-shaped. As used herein, “ring-shaped” or the like may include square ring-shaped, circular ring-shaped, or other types of ring-shaped. In some embodiments, the plurality of cutting paths HS extend substantially parallel to each other along the direction D2, and extend cross the edge parts RP2 of a plurality of dies 120 close to the side edges S1a and S1b; the plurality of cutting paths VS extend substantially parallel to each other along the direction D3, and include a plurality of cutting paths VS1 that extend across the edge parts RP2 of the plurality of dies 120 close to the side edges S2a and S2b and a plurality of cutting paths VS2 that extend across middle parts of the plurality of dies 120, wherein the middle parts extend in the direction D3.

In some embodiments, as illustrated in the enlarged view of FIG. 4A, the cutting process partially cuts the substrate 100 along the cutting paths HS to remove the edge parts RP2 close to the side edges S1a and S1b, and the cutting process removes the edge parts RP2 close to the side edges S2a and S2b along the cutting paths VS1. In this way, the edge parts RP2 of the substrate 100 close to the respective side edges are all removed, and a substrate recess RS is formed at the positions where the edge parts RP2 were previously located. Moreover, the cutting process further cuts the substrate 100 along the cutting path VS2 to remove the middle part RP1 of the die 120. In some embodiments, each die 120 is crossed by one or more cutting paths VS2, so that one or more middle parts PR1 of each die 120 are removed, thereby forming one or more trenches TH at the position where the one or more middle parts PR1 were previously located. As illustrated in FIG. 4A, the edge parts RP2 of the substrate 100 close to the side edges S1a and S1b are each crossed by a cutting path VS and a cutting path HS that intersect with each other, thus may undergo cutting processes along the cutting path VS and the cutting path HS, but they may also each only undergo a cutting process along the cutting path HS; while the edge parts RP2 of the substrate 100 close to the side edges S2a and S2b are each crossed by a single cutting path VS1, thus undergo a cutting process along the single cutting path. However, the present disclosure is not limited thereto.

In the steps of FIGS. 4A and 4B, the cutting process is only used to remove parts of the substrate of the die to form trenches and recess in the substrate 100, but is not used to cut through the wafer WF. After the cutting process, the plurality of dies 120 are still connected with each other and located in the same wafer WF without being sliced into independent dies. That is to say, a cutting depth along the above-mentioned cutting path HS/VS (i.e., a thickness of the removed part RP1/PR2) is smaller than a thickness of the die 120, and may be smaller than a thickness of the substrate 100.

As compared with the embodiment of FIG. 1A to 1B in which parts of the substrate 100 are removed by a patterning process including photolithography and etching, the process of removing parts of the substrate 100 by using a cutting process in some embodiments is simpler and highly efficient with lower cost, and trenches and recess with larger sizes can be formed, so that the heat dissipation filling structure with a higher content can be subsequently filled in the trenches. In this embodiment, the cutting paths of the cutting process includes edge cutting path(s) (HS and VS1) crossing all the edge parts of each die and cutting path(s) VS2 crossing the middle part(s) of the die 120 in the direction D3, thereby forming a ring-shaped recess RS and one or more strip-shaped trenches TH extending in the direction D3. It should be understood that the cutting paths illustrated in FIG. 4A is only for illustration, and the present disclosure is not limited thereto.

In some other embodiments, on the basis of cutting along the above-mentioned paths, the cutting process may further include cutting along a plurality of cutting paths which extend in the direction D2 and cross the middle parts of a plurality of dies 120, so as to remove one or more middle parts of the substrate 100 extending in the direction D2 and form one or more trenches extending in the direction D2; the one or more trenches extending in the direction D2 and one or more strip-shaped trenches TH are intersected with each other and spatially communicated with each other, thereby forming a cross-shaped trench or a grid-shaped trench (for example, as illustrated in FIG. 2D). In yet some other embodiments, the cutting process does not include a cutting path VS2 which extends in the direction D3 and crosses the middle part of the die 120, but includes a cutting path which extends in the direction D2 and crosses one or more middle parts of the die 120, thereby forming a plurality of strip-shaped trenches extending in the direction D2 (for example, as illustrated in FIG. 2B). In addition, one or more of the edge parts of the die 120 close to respective side edges may not be crossed by the cutting path, so that only a part of the edges of the die 120 is recessed. It should be understood that the above-mentioned cutting paths and the shapes of the trenches and recess as formed are only for illustration, and the present disclosure is not limited thereto. The cutting paths can be adjusted according to product requirements, as long as the trenches for filling the heat dissipation filling structure and the recess for increasing the surface area of the back surface of the die are formed, and the number and shapes of the trenches and recess are not limited.

FIG. 5A and FIG. 5B illustrate a top view and a cross-sectional view of the die 120 after the cutting process, respectively, and FIG. 5B is taken along a line I-I′ of FIG. 5A.

Referring to FIG. 5A and FIG. 5B, in some embodiments, after the cutting process, one or more trenches TH and a recess RS are formed in the substrate 100, the trenches TH and the recess RS extend from the back surface of the substrate towards the front side of the die in a direction perpendicular to the main surface of the substrate 100 (e.g., direction D1), and extend into the substrate 100, and depths of the trenches TH and the recess RS in a direction perpendicular to the main surface of the substrate (e.g., direction D1) are smaller than the thickness of the substrate 100. In some embodiments, the trench TH extends in a direction parallel to the main surface of the substrate 100 (for example, the direction D3) and passes through the substrate, and the recess RS is located at the edge of the substrate 100 and may have a ring shape, for example. The trench TH and the recess RS may be in spatial communication with each other.

In other words, after the above-mentioned cutting process including a trenching process and a trimming process is performed on the substrate 100, the substrate 100 includes a body part 100a and a protruding part 100b, and the body part 100a is located between the protruding part 100b and the device layer 191; the protruding part 100b is protruded from a surface of the body part 100a at a side away from the device layer 101 (i.e., the top surface illustrated in the figure) in a direction perpendicular to the main surface of the substrate (for example, the direction D1). In some embodiments, the trench TH is located between adjacent protruding parts 100b, and a plurality of protruding parts 100b are spaced apart from each other by the trench TH located therebetween; the recess RS is located above an edge of the body part 100a and laterally surrounds the plurality of protruding parts 100b in a direction parallel to the main surface of the substrate.

In some embodiments, during the cutting process, cutting depths along the respective cutting paths are substantially the same as each other, so that a depth d1 of the trench TH and a depth d2 of the recess RS of the substrate 100 are substantially the same as each other, but the present disclosure is not limited thereto. In some other embodiments, the cutting depths of the cutting process along the respective cutting paths may also be different from each other, so that the depth d1 of the trench TH as formed may be different from the depth d2 of the recess RS, and the depths d1 of different trenches TH may also be different from each other; alternatively, the cutting depths along parts of the cutting paths are as same as each other, and the cutting depths along another parts of the cutting paths may be different from each other, so that the one or more trenches TH as formed and a plurality of regions of the recess RS may have the same depth or different depths. It should be understood that in this embodiment, the cutting process starts cutting from the back side of the substrate of the die 100 towards the front side of the substrate 100, and the “cutting depth” refers to a depth at a position in the substrate 100 where the cutting process stops cutting, that is, a distance from the position where the cutting is stopped to the back surface of the substrate in the direction D1; the “cutting depth” is substantially equal to a thickness of the corresponding removed part RP1, RP2 of the substrate in the direction D1 as illustrated in FIG. 4B, and is substantially equal to a depth d1, d2 of the corresponding trench TH, recess RS as illustrated in FIG. 5B.

Referring to FIG. 6A and FIG. 6B, a heat dissipation filling structure 106 is then formed to fill the trench TH of the substrate 100. In some embodiments, a barrier layer 105 is further formed between the heat dissipation filling structure 106 and the substrate 100. The heat dissipation filling structure 106 may include a material having a thermal conductivity greater than that of the substrate 100. For example, the heat dissipation filling structure 106 may include a metal material such as copper, silver, or the like; the barrier layer may include a metal material such as titanium, or an insulating material such as silicon oxide, silicon nitride, or the like. The barrier layer 105 is formed between the heat dissipation filling structure 106 and the substrate 100 to separate the heat dissipation filling structure 106 from the substrate, and can be used to prevent the metal materials of the heat dissipation filling structure 106 from diffusing to the substrate 100. When the heat dissipation filling structure 106 includes a metal material, the heat dissipation filling structure 106 is electrical floating, that is, the heat dissipation filling structure 106 is electrically isolated from other components in the die 120 (for example, devices and/or conductive structures in the device layer 101, etc.) and other components in the subsequently formed package structure. In some other embodiments, the heat dissipation filling structure 106 may also include nonmetal materials or other types of materials, as long as the thermal conductivity of the heat dissipation filling structure 106 is greater than that of the substrate. In the embodiments where the heat dissipation filling structure 106 includes nonmetal materials or has no electrical conductivity, the barrier layer 105 may also be omitted.

In some embodiments, the heat dissipation filling structure 106 and the barrier layer 105 are filled in the trench TH, but not filled in the recess RS. As illustrated in FIG. 6A, sidewalls of the heat dissipation filling structure 106 and the barrier layer 105 opposite in a direction parallel to the main surface of the substrate (for example, the direction D3) and sidewalls of the protruding part 100b of the substrate opposite in the direction D3 may be substantially level with each other in the direction D2. That is to say, the respective sidewalls of the heat dissipation filling structure 106 and the barrier layer 105 opposite in the direction D3 are exposed by the substrate 100, and are exposed in the recess RS along with the sidewalls of the protruding part 100b.

In some embodiments, the barrier layer 105 and the heat dissipation filling structure 106 may be formed by the following processes: forming a barrier material layer and/or a seed material layer at the back side of the substrate 100 after forming the trenches TH and the recess RS; the barrier material layer may include a metal material such as titanium, or an insulating material such as silicon oxide, silicon nitride, or the like; the seed layer is a metal seed layer required for subsequent formation of a metal layer by a plating process such as electroplating, such as a seed layer for copper plating, and may be formed by sputtering or other processes; a material of the seed layer may include titanium, copper, alloys thereof or combinations thereof, and may also have high thermal conductivity, that is, the thermal conductivity of the seed layer is greater than that of the substrate 100. In some embodiments, the materials of the barrier material layer and the seed layer are different from each other, and the barrier material layer is formed on the substrate, while the seed layer is formed at a side of the barrier material layer away from the substrate. The barrier material layer and the seed layer are formed on the back side of the substrate 100 to cover the back surface of the substrate 100, and are filled in the trench(es) TH and the recess RS, so as to line the surfaces of the trenches TH and the recess RS. Thereafter, a mask layer (for example, a patterned photoresist layer) is formed on the substrate 100 to cover parts of the seed layer located in the recess RS and located on the protruding parts 100b, and the mask layer has an opening corresponding to the trench(es) TH to expose the seed layer located in the trench(es) TH; then a heat dissipation material layer (for example, a metal material layer) is formed on the seed layer in the trench(es) TH exposed by the opening of the mask layer to fill a space of the trench(es) TH not filled by the barrier layer, so that the heat dissipation material layer fills up the trench TH, but the present disclosure is not limited thereto. Then, the mask layer is removed, for example, the patterned photoresist may be removed by a process such as ashing or stripping. Thereafter, for example, the seed layer and the barrier material layer located outside the trench (es) TH may be removed by an etching process, and the heat dissipation material layer and the seed layer remained in the trench form the heat dissipation filling structure 106, while the remained barrier material layer forms the barrier layer 105.

It should be understood that, the above processes are only for illustration, and the present disclosure is not limited thereto. In some other embodiments, the materials of the barrier material layer and the seed layer are the same, for example, both including titanium, so the barrier material layer and the seed layer may share one layer of material, that is, the barrier material layer can also be used as the seed layer. In some other embodiments where the heat dissipation structure is formed of nonmetal materials, the barrier material layer and the seed layer may be omitted.

Referring to FIG. 7A and FIG. 7B, a cutting process is performed on the wafer WF to realize singulation of a plurality of dies 120′ and form a plurality of dies 120a that are independent of each other. The cutting process may also be referred to as a singulation process, and may also be referred to as a second cutting process. For example, the cutting process cuts the wafer WF along cutting paths SR, which extend along scribe lines between a plurality of dies respectively, and are in a grid shape, for example. In some embodiments, the cutting process may include a mechanical saw process, a laser dicing process, other types of cutting processes, or a combination thereof. What is different from the first cutting process illustrated in FIG. 4A is that, in this step, the cutting process is to cut along scribe lines between the dies, without extending across the die regions to remove parts of the dies; moreover, a cutting depth of this cutting process is greater than that of the cutting process illustrated in FIG. 4A. In this step, the cutting process cuts through the wafer WF to singulate the plurality of dies 120′ and form a plurality of dies 120a independent of and separated from each other. In some embodiments, the abovementioned first cutting process and second cutting process may use the same cutting apparatus, and a cutting path of the cutting apparatus is programmed, so that the first cutting process and the second cutting process cut the wafer along different cutting paths at different cutting depths based on process requirements.

In some embodiments, during the process of FIG. 3A, FIG. 3B to FIG. 6A, and FIG. 6B, the wafer WF is placed on a temporary carrier, which provides a structural support for the wafer WF during the manufacturing process; and after the process of filling the heat dissipation structure in FIGS. 6A and 6B is completed, the wafer WF is de-bonded from the temporary carrier and placed on a tape, for example, a back side of the wafer WF is placed on the tape, and a cutting process may be performed from a front side of the wafer WF which is provided with conductive bumps 102, but the present disclosure is not limited thereto. After the cutting process is performed to form a plurality of dies 120a, the dies 120a may be removed from the tape and used for the subsequent packaging process.

Referring to FIG. 8, in some embodiments, a package substrate 200 is provided, and a die 120a is mounted on the package substrate 200. For example, the die 120a is electrically connected to the package substrate 200 through a plurality of conductive bumps 102. For example, the package substrate 200 may include a core layer 201, build-up layers 202a and 202b, and solder resist layers 203a and 203b. The build-up layers 202a and 202b are located on two opposite sides of the core layer 201 respectively, and the solder resist layers 203a and 203b are locate on sides of the build-up layers 202a and 202b away from the core layer 201, respectively. In some embodiments, the core layer 201 includes a core dielectric layer and a conductive structure. The core dielectric layer may include a prepreg, and a material of the prepreg includes resin materials such as epoxy resin, silica fillers and/or glass fibers. Alternatively, the core dielectric layer may also include Ajinomoto Buildup Film (ABF), polyimide, or other polymer materials, or other types of core materials. The conductive structure in the core layer 201 may include conductive vias penetrating through the core dielectric layer and/or conductive lines located on two opposite sides of the core dielectric layer; the conductive lines and vias are connected with each other and used for electrical connection with conductive layers in the build-up layers. The build-up layers 202a and 202b may each include one or more dielectric layers and conductive layers stacked on each other, and the one or more conductive layers are embedded in the dielectric layers and electrically connected to the conductive structure in the core layer 201. In some embodiments, the solder resist layers 203a and 203b each have one or more openings to expose part of conductive layer (e.g., conductive pads) in the build-up layer 202a, 202b for further electrical connection. For example, at least part of the conductive pads (not illustrated) exposed by the solder resist layer 203b are electrically connected to the conductive bumps 102 of the die 120a.

In some embodiments, an additional device 205 may also be provided on the package substrate 200, and the additional device 205 may be or include an electronic device such as a capacitor, for example, and the present disclosure does not limit the type of the additional device. The electronic device 205 is electrically connected to the package substrate 200 and may be coupled to the die 120a. In some embodiments, the electronic device 205 and the die 120a are disposed on the same side of the package substrate 200, but the present disclosure is not limited thereto. In some other embodiments, the electronic device 205 and the die 120a may also be disposed on opposite sides of the package substrate 200. It should be understood that, the positions and numbers of the electronic devices 205 illustrated in the figure are only for illustration, and the present disclosure is not limited thereto.

Referring to FIG. 9, an underfill layer 108 is formed between the die 120a and the package substrate 200, so as to fill a space between the die 120a and the package substrate 200 and to surround and protect the plurality of conductive bumps 102.

Referring to FIG. 10, a thermal dissipation component 110 is mounted on the package substrate 200 and attached to the back side of the die 120a for heat dissipation of the die 120a. For example, the thermal dissipation component 110 is attached to the package substrate 200 through an adhesive layer 302, and is attached to the back side of the die 120a through a thermal interface material layer 109. In some embodiments, the thermal interface material layer 109 extends along the back surface of the die 120a and extends into the recess RS of the substrate; the thermal dissipation component 110 includes a heat dissipation body part 110a and a heat dissipation protrusion 110b, and the heat dissipation protrusion 110b has a shape corresponding to the recess RS of the die 120a and extends into the recess RS of the die 120a. In this embodiment, the thermal dissipation component 110 is a heat dissipation lid, but the present disclosure is not limited thereto.

Referring to FIG. 11, thereafter, a plurality of conductive bumps 220 are formed on a side of the package substrate 200 opposite to the die 120a. The plurality of conductive bumps 220 are electrically connected to the die 120a through the package substrate 200. In this way, a package structure 500a is thus formed.

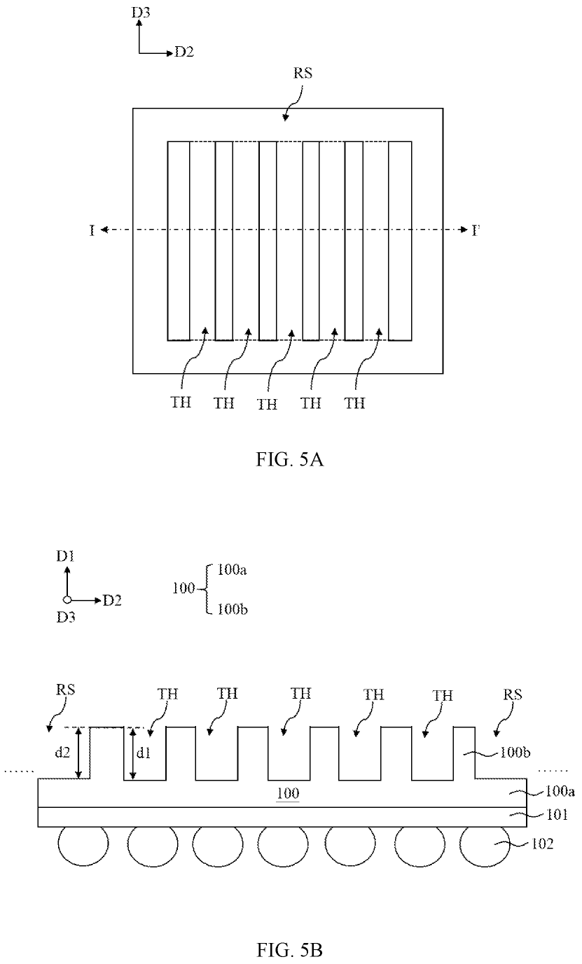

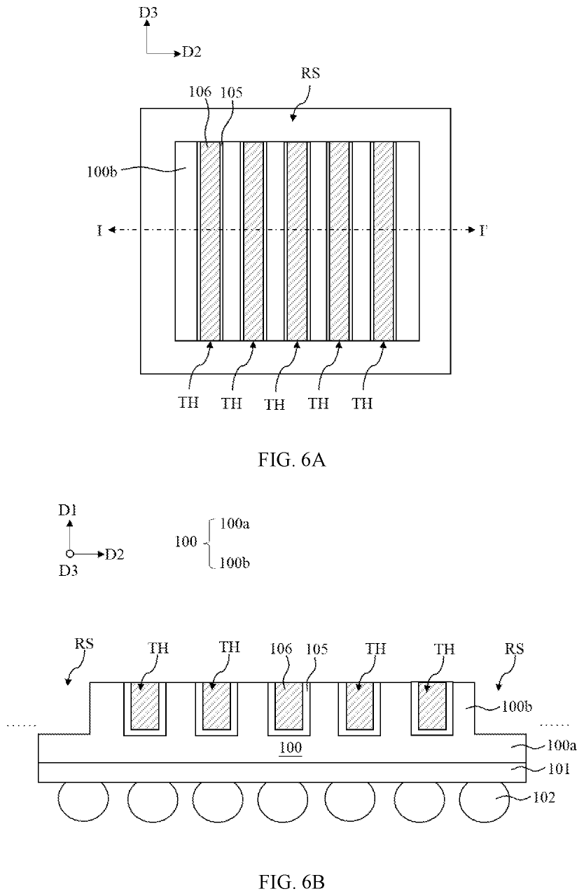

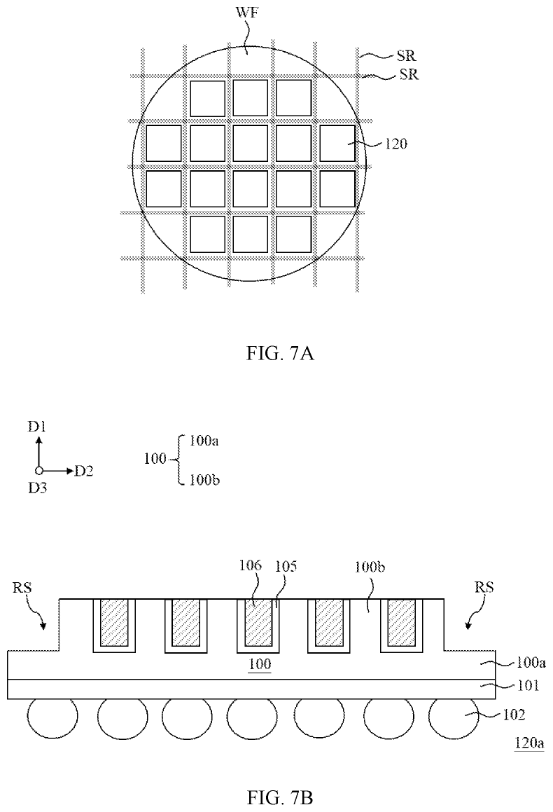

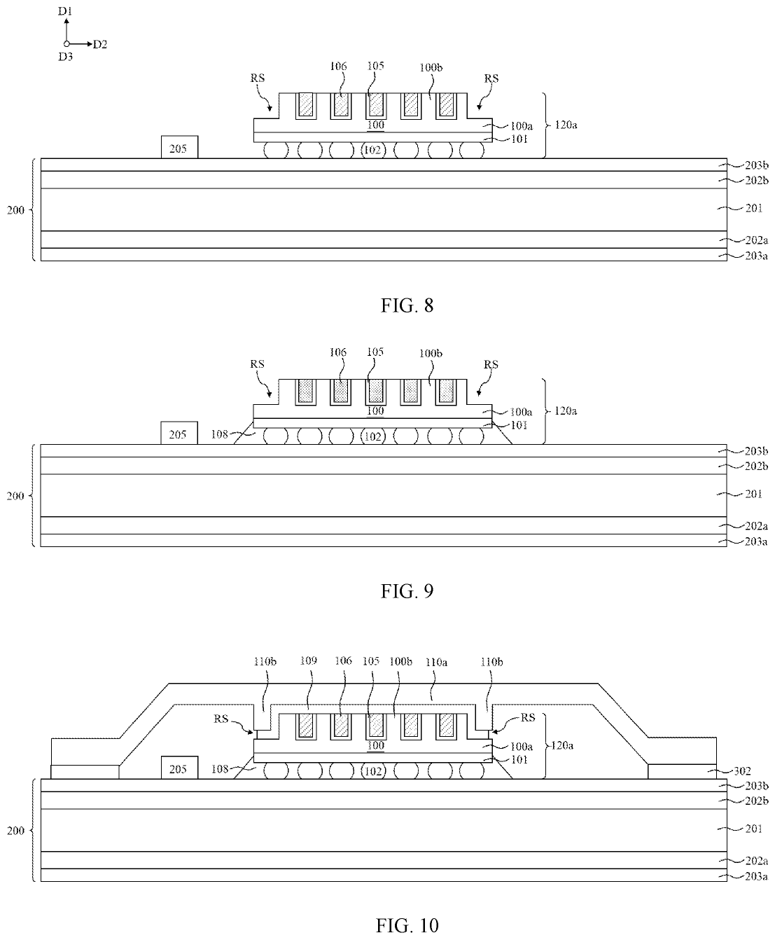

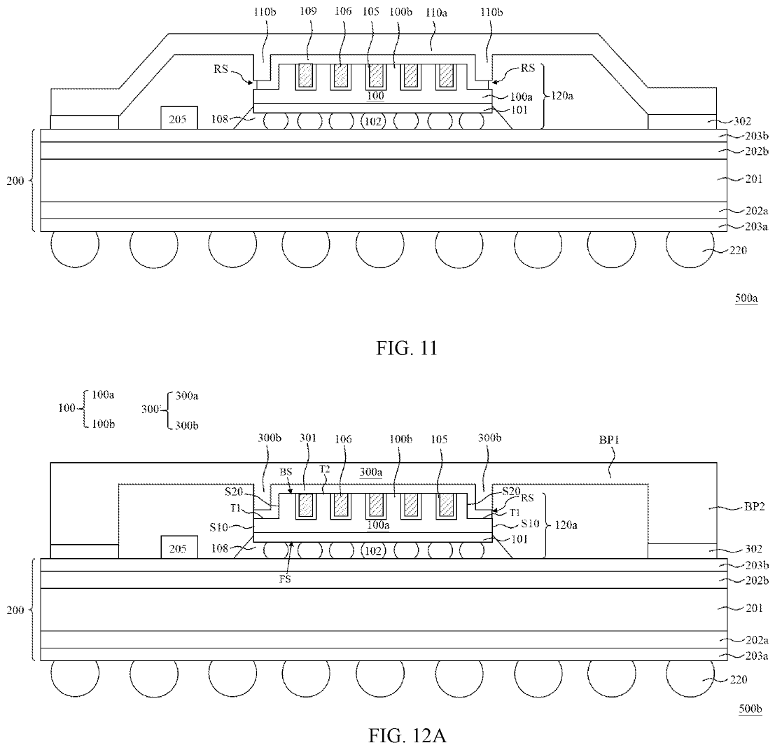

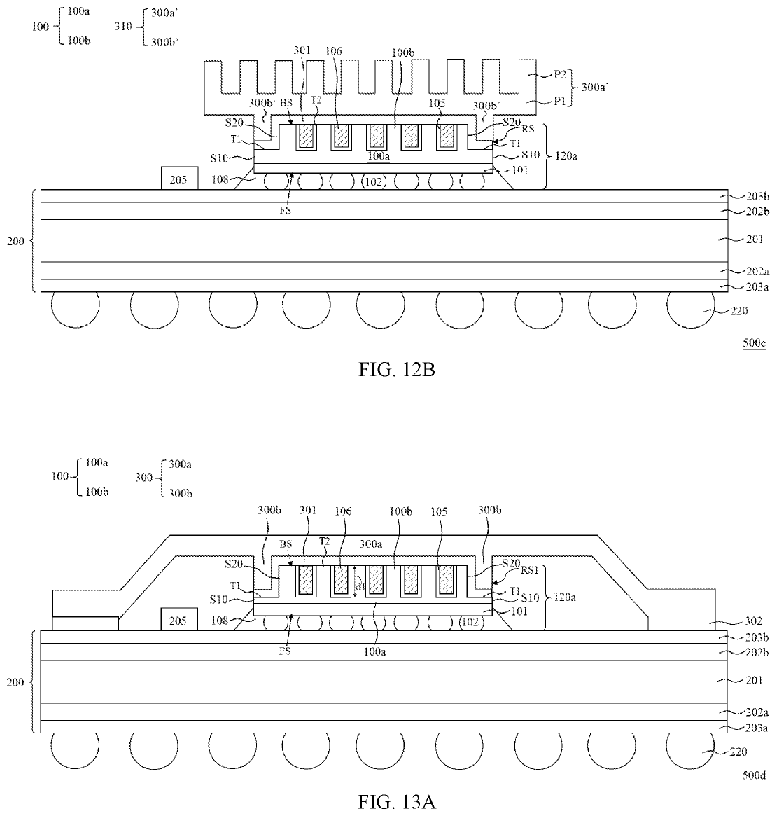

FIG. 12A and FIG. 12B illustrate schematic cross-sectional views of a package structure according to some alternative embodiments of the present disclosure. The package structures illustrated in FIG. 12A and FIG. 12B are similar to those of the previous embodiments, with the difference that the shapes or types of thermal dissipation components of these package structures are different.

Referring to FIG. 12A, in some embodiments, the package structure 500b is similar to the package structure 500a, with the difference that the shape of the thermal dissipation component 300′ of the package structure 500b is slightly different from that of the thermal dissipation component 300 of the package structure 500a. In this embodiment, the thermal dissipation component 300′ also adopts a heat dissipation lid, and has a heat dissipation body part 300a and a heat dissipation protrusion 300b. The heat dissipation body part 300a includes a horizontal extension part (or may be referred to as a heat dissipation plate) BP1 extending in a direction parallel to the main surface of the die and a landing part (or may be referred to as a heat dissipation pillar) BP2 extending in a direction perpendicular to the main surface of the die. The heat dissipation pillar has a ring shape, for example, and laterally surrounds the die 120a and the heat dissipation protrusion 300b, and is laterally spaced apart from the die 120a and the heat dissipation protrusion 300b. In this embodiment, the heat dissipation plate BP1 and the heat dissipation pillar BP2 extend to be directly connected with each other, the heat dissipation plate BP1 is connected with the heat dissipation protrusion 300b, and the heat dissipation pillar BP2 is attached to the package substrate 200 through the adhesive layer 302.

Referring to FIG. 12B, in some embodiments, in the package structure 500c, a heat sink is used as the thermal dissipation component 310. The thermal dissipation component 310 is attached to the back side of the die 120a through the thermal interface material layer 301. In this embodiment, the thermal dissipation component 310 is not attached to the package substrate 200 through an adhesive layer. Similar to the previous embodiments, the thermal dissipation component 310 includes a heat dissipation body part 300a′ and a heat dissipation protrusion 300b′, and the relative positional relationships among the heat dissipation protrusion 300b′, the thermal interface material layer 301 and the die 120a are similar to those described with respect to the package structure 500a, which is not repeated here.

In some embodiments, the heat dissipation body part 300a′ includes a heat dissipation plate P1 extending in a direction parallel to the main surface of the die and a plurality of heat dissipation protrusions P2 located on the heat dissipation plate P1. That is to say, the thermal dissipation component 310 (i.e., the heat sink) includes a heat dissipation plate P1, heat dissipation protrusions P2 and a heat dissipation protrusion 300b′, and the heat dissipation protrusions P2 and the heat dissipation protrusion 300b′ are protruded from the heat dissipation plate P1 along opposite directions in a direction perpendicular to the main surface of the die. The heat dissipation protrusion 300b′ is located on a side of the heat dissipation plate P1 close to the die 120a and extends into the recess RS of the substrate of the die, and the heat dissipation protrusion P2 is located on a side of the heat dissipation plate P1 away from the heat dissipation protrusion 300b′ and the die 120a.

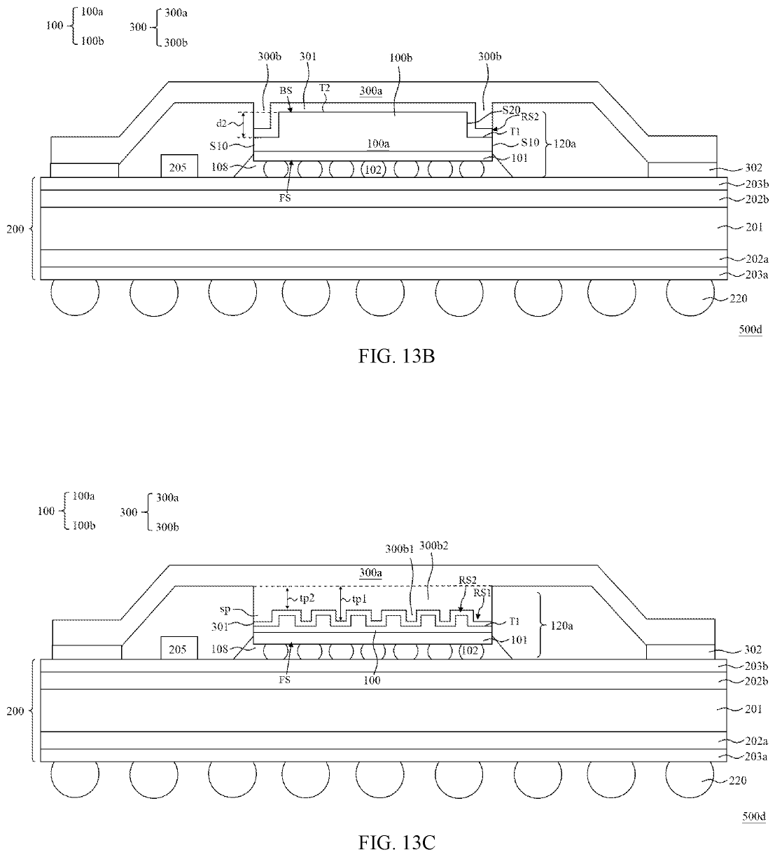

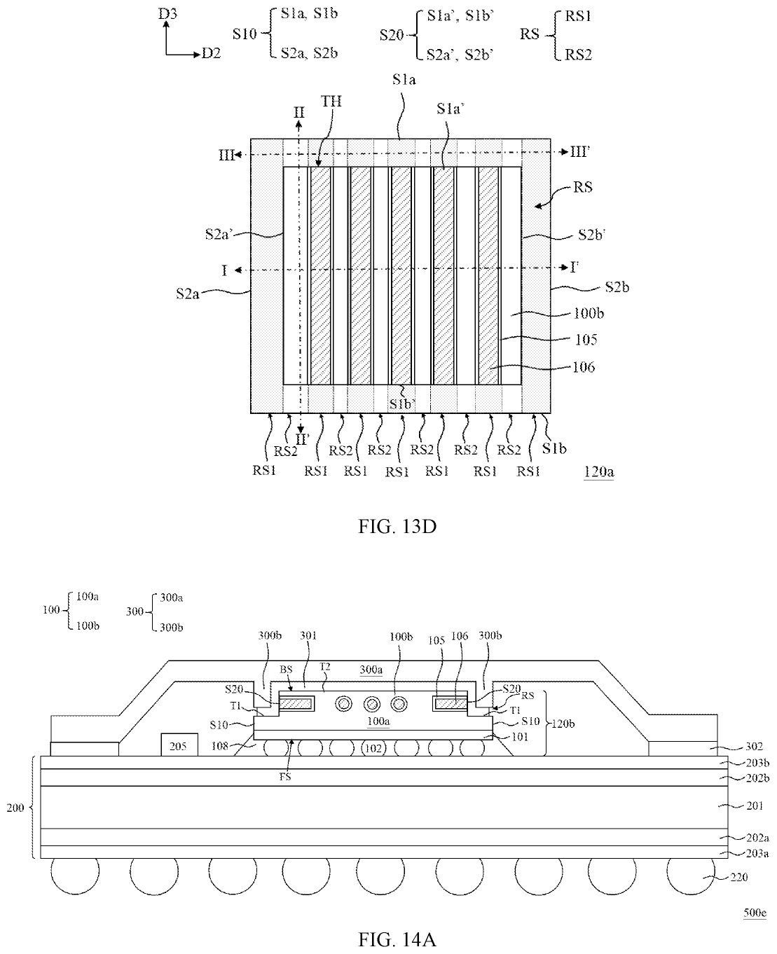

FIG. 13A to FIG. 13D illustrate schematic cross-sectional views and a schematic plan view of a package structure 500d according to some other embodiments of the present disclosure, wherein FIG. 13A, FIG. 13B and FIG. 13C are cross-sectional views taken along lines I-I′, II-II′ and III-III′ of FIG. 13D, respectively.

Referring to FIG. 4A and FIG. 4B and FIG. 13A to FIG. 13D, in some embodiments, during the process of performing the cutting process on the wafer to form trenches and recess, the cutting process may cut the substrate at different depths (i.e., different thicknesses of the removed parts RP1 and RP2 of the substrate) along different cutting paths, so that the plurality of trenches and the recess formed in the substrate may have different depths. In some embodiments, the substrate recess may include a plurality of sub-recesses with different depths and in spatial communication with each other; correspondingly, the heat dissipation protrusion of the thermal dissipation component has a shape corresponding to the substrate recess, for example, the heat dissipation protrusion may also include a plurality of sub-protrusions extending into the sub-recesses with a larger depth of the substrate recess.

For example, in some embodiments, during the first cutting process illustrated in FIG. 4A and FIG. 4B, the cutting depth of the cutting path along the direction D2 may be different from the cutting depth of the cutting path along the direction D3; for example, the cutting depths along the respective cutting paths HS may be substantially the same as each other, the cutting depths along the cutting paths VS1 and VS2 may be substantially the same as each other, and the cutting depth along the cutting paths HS may be smaller than that along the cutting paths VS1 and VS2. In this way, the depth of the trench TH formed in the substrate 100 may be greater than the depth of a part of the recess RS. Specifically, a part of the recess RS along the direction D3 is formed by cutting the substrate along the cutting path VS1 through the cutting process, therefore, this part of the recess RS along the direction D3 has substantially the same and uniform depth as the trench TH. While a part of the recess RS along the direction D2 is located at a position where the cutting path VS and the cutting path HS intersect, and thus may be formed by cutting the substrate along both the cutting path VS and the cutting path HS through the cutting process; because the cutting depth along the cutting path VS is greater than that along the cutting path HS, this part of the recess RS along the direction D2 has uneven depths, for example, including a plurality of recess regions with different depths.

Referring to FIG. 13A to FIG. 13D, in some embodiments, the recess RS of the substrate 100 includes a first sub-recess RS1 and a second sub-recess RS2. A depth d1 of the first sub-recess RS1 is greater than a depth d2 of the second sub-recess RS2, and the depth d1 of the first sub-recess RS1 may be substantially equal to a depth of the trench TH in the substrate 100. The first sub-recess RS1 and the second sub-recess RS2 are spatially communicated with each other, and the recess RS has a ring shape as a whole. In some embodiments, a part of the recess RS close to the side edges S2a′ and S2b′ of the substrate is first sub-recesses RS1 with a larger depth d1, while a part of the recess RS close to the side edges S1a′ and S1b′ of the substrate has first sub-recesses RS1 and second sub-recesses RS2 alternately arranged.

In some embodiments, as illustrated in FIG. 13C, because the recess RS has a first sub-recess and a second sub-recess with different depths, a part of the first back surface T1 of the substrate has an uneven surface. In some embodiments, the thermal interface material layer 301 is a conformal layer, and a part thereof filled in the recess RS of the substrate 100 also has an uneven surface. In some embodiments, the thermal dissipation component 300 has a heat dissipation protrusion 300b extending into the recess RS of the substrate 100, and the heat dissipation protrusion 300b may have a shape corresponding to the recess RS of the substrate 100. For example, the heat dissipation protrusion 300b has a first part 300b1 and a second part 300b2, and the first part 300b1 and the second part 300b2 are respectively configured to correspond to the first sub-recess RS1 and the second sub-recess RS2 of the substrate 100. For example, the first part 300b1 and the second part 300b2 of the heat dissipation protrusion 300b are disposed in the first sub-recess RS1 of the substrate 100b, and the second part 300b2 further extends into the second sub-recess RS2 of the substrate 100b; accordingly, a protruding length tp1 of the first part 300b1 is greater than a protruding length tp2 of the second part 300b2. It should be understood that, herein, the “protruding length” refers to a length of the part of the heat dissipation protrusion protruded from the heat dissipation body part 300a towards the back surface T1 of the substrate; that is, a distance from the heat dissipation body part of the thermal dissipation component 300 to the surface of the heat dissipation protrusion facing the back surface of the substrate in a direction perpendicular to the main surface of the die.

That is to say, the heat dissipation protrusion 300b includes a first part 300b1 and a second part 300b2 with different protruding lengths; the first part 300b1 with a larger protruding length protrudes from the second part 300b2 in a direction perpendicular to the main surface of the die, and protrudes from the second part 300b2 towards the recess RS1 of the substrate 100 with a larger depth. In other words, the heat dissipation protrusion 300b includes a protrusion body and a plurality of sub-protrusions sp, and the sub-protrusion is protruded from the protrusion body, for example, in the direction D1, and extends into the sub-recess RS1 with a larger depth.

In this embodiment, by adjusting the cutting depths along different cutting paths during the cutting process, the recess as formed has a plurality of sub-recesses with different depths, that is, the recess has an uneven morphology, thus further increasing the surface area of the back side of the die (for example, increasing the surface area of the back surface T1) as compared with the previous embodiments; moreover, the thermal interface material layer and the heat dissipation protrusion extend into the respective sub-recesses correspondingly, thereby further increasing the contact area between the thermal interface material layer and the die and the contact area between the thermal dissipation component and the thermal interface material layer; that is to say, the heat dissipation area of the die is further increased, and hence the heat dissipation performance of the die can be further improved.

FIG. 14A illustrates a schematic cross-sectional view of a package structure according to some other embodiments of the present disclosure, FIG. 14B illustrates a schematic plan view of a die of the package structure illustrated in FIG. 14A according to some other embodiments of the present disclosure, and the cross-sectional view of the die in the package structure illustrated in FIG. 14A is taken along a line IV-IV′ of FIG. 14B.

Referring to FIG. 14A and FIG. 14B, in some embodiments, the package structure 500c is similar to the aforementioned package structure, with the difference that in the die of the package structure of the aforementioned embodiment, the heat dissipation filling structure 106 extends into the substrate from the back surface T2 of the substrate 100; while in the die 120a of the package structure 500c, the heat dissipation filling structure 106 extends into the substrate from the sidewall S20 of the substrate 100.

For example, the heat dissipation filling structure 106 may include one or more heat dissipation filling blocks extending into the substrate from one or more side edges of the sidewall S2a of the die. In some embodiments, the heat dissipation filling structure 106 does not extend to penetrate through the substrate in a direction parallel to the main surface of the substrate, but passes through a part of the substrate and is embedded in the substrate. For example, each heat dissipation filling block of the heat dissipation filling structure 106 has a sidewall S3 exposed by the substrate and a sidewall S4 opposite to the sidewall S3 in a direction parallel to the main surface of the die. That is to say, the heat dissipation filling structure 106 has a part exposed at the sidewall of the substrate, i.e., the sidewall S3 of the heat dissipation filling structure 106. In some embodiments, the sidewall S4 of the heat dissipation filling structure 106 is not exposed by the substrate, but is embedded in and covered by the substrate. In this embodiment, the protruding part 100b of the substrate is continuous, and one or more heat dissipation blocks of the heat dissipation filling structure 106 may be embedded in an edge part of the protruding part 100b.

Similar to the previous embodiments, a barrier layer 105 may be disposed between the heat dissipation filling structure 106 and the substrate 100, for example, the barrier layer 105 surrounds a top surface, a bottom surface and a sidewall S4 of the heat dissipation filling structure 106. The sidewall S20 of the die includes a sidewall of the protruding part 100b of the substrate 100, a sidewall S3 of the heat dissipation filling structure 106, and a sidewall of the barrier layer 105.

In some embodiments, as illustrated in FIG. 14A, both the top surface and the bottom surface of the heat dissipation filling structure 106 are covered by the substrate, and parts of the barrier layer 105 are located between the top surface of the heat dissipation filling structure 106 and the substrate, and between the bottom surface of the heat dissipation filling structure and the substrate.

In some embodiments, the forming process of the package structure 500e is similar to the previous embodiments, with the difference that in the package structure 500e, the trench TH of the substrate 100 is formed by removing part of the substrate from the sidewall of the substrate, and may be formed by a cutting process using laser, which may include, for example, a laser drilling process, or the like. The recess RS of the substrate 100 may be formed by a cutting process such as mechanical cutting, laser cutting, or the like. In this embodiment, the recess RS and the trench TH of the substrate 100 may be formed successively by different cutting processes. For example, firstly, an edge part of the substrate 100 is removed by using a cutting process to form a recess RS at the edge of the substrate 100, so that the substrate 100 has a body part 100a and a protruding part 100b, and has a sidewall S10 and a sidewall S20 which are laterally offset from each other; then a laser drilling process is performed on the substrate from the sidewall S20 of the substrate 100 to remove a part of the substrate 100 (i.e., a part of the protruding part 100b), thereby forming trench(es) TH extending from the sidewall S20 of the substrate 100 into the substrate; thereafter, a barrier layer 105 and a heat dissipation filling structure 106 are formed in the trench(es) TH.

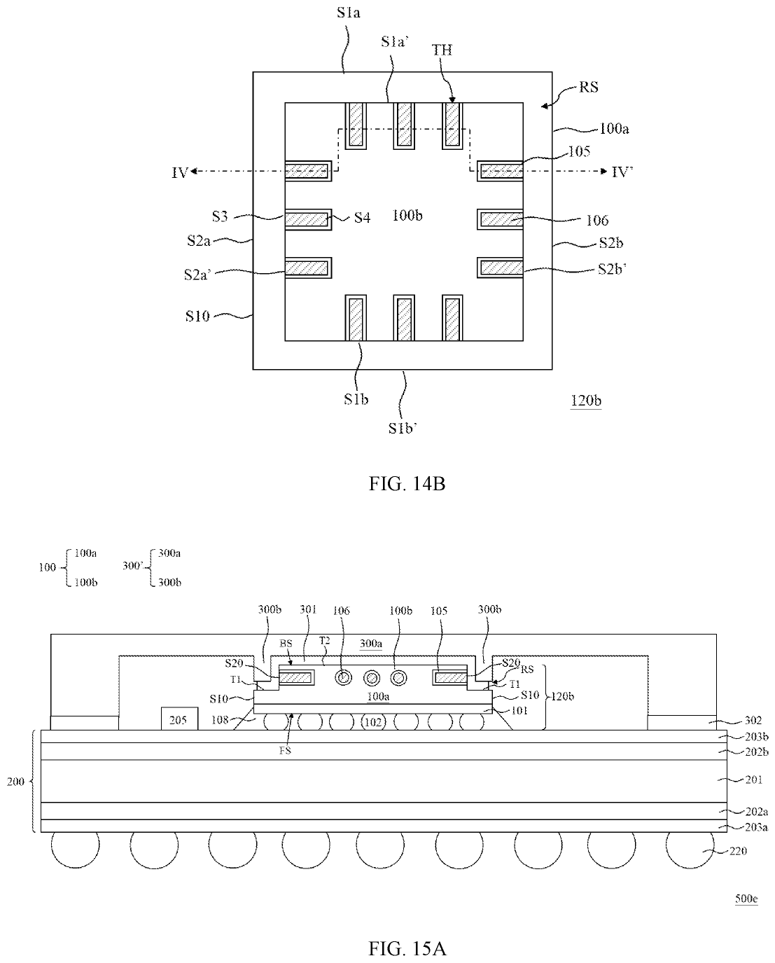

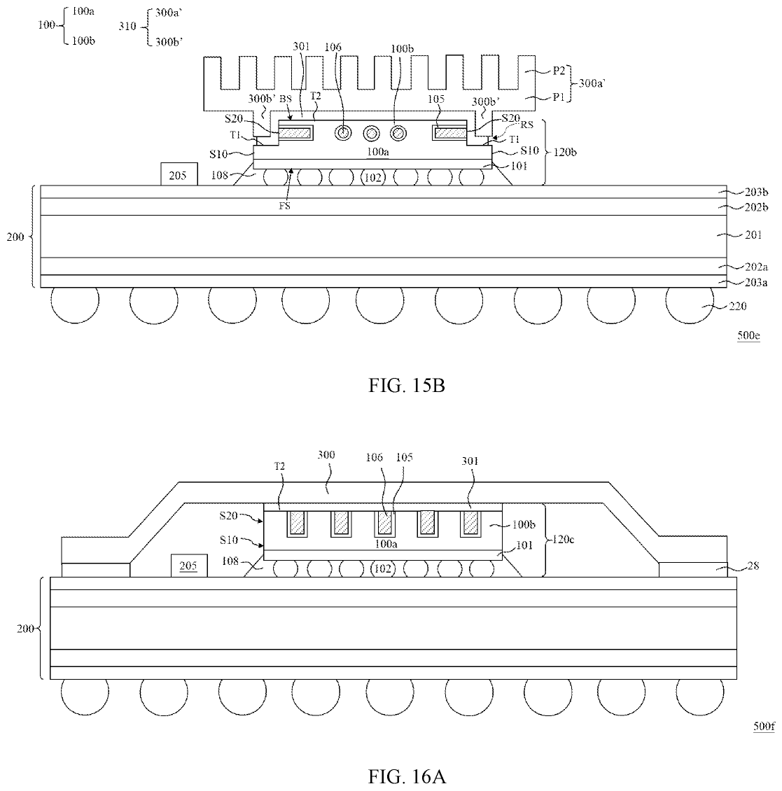

In some embodiments, other types of thermal dissipation components may also be used as the thermal dissipation component of the package structure 500c, for example, the heat dissipation lid 300′ illustrated in FIG. 15A or the heat sink 310 illustrated in FIG. 15B can be adopted. The structures of the heat dissipation lid 300′ and the heat sink 310 are similar to those of the previous embodiments, which will not be repeated here.

In each of the package structures 500a-500e of the above embodiments, the substrate of the die has a heat dissipation filling structure embedded therein and further includes a substrate recess, so as to improve the thermal conductivity of the substrate of the die and also increase the heat dissipation area of the die, thus reducing the thermal resistance of the die by improving the thermal conductivity of the material of the die on the one hand and increasing the heat dissipation area on the other hand, thereby improving the heat dissipation performance of the die and the package structure. However, the present disclosure is not limited thereto. In some other embodiments, the heat dissipation performance of the die and the package structure can also be improved by providing one of the heat dissipation filling structure and the substrate recess in the substrate of the die.

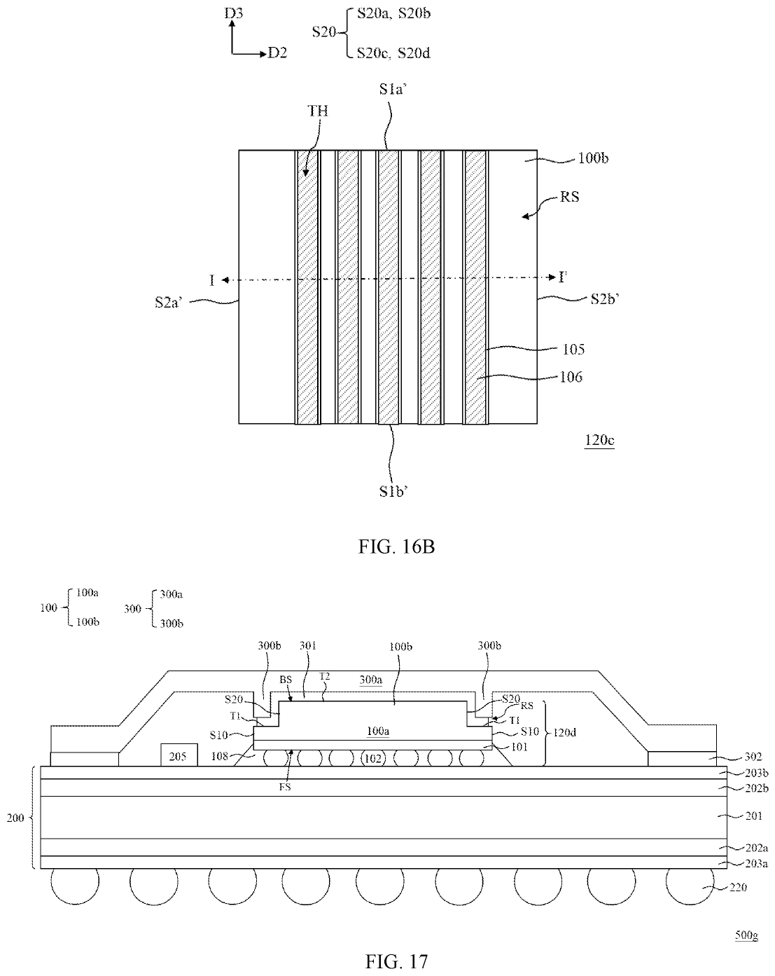

For example, referring to FIG. 16A and FIG. 16B, in some embodiments, the package structure 500f is similar to the package structure 500a, with the difference that no recess RS is provided in the die 120c of the package structure 500d. As illustrated in FIGS. 16A and 16B, in some embodiments, the die 120c has a heat dissipation filling structure 106 embedded in the substrate 100, and there is no recess disposed at the edge of the substrate 100. The structure and forming method of the heat dissipation filling structure 106 are similar to those described in the previous embodiments. The sidewall S10 of the die (i.e., the sidewall of the body part 100a of the substrate 100) and the sidewall S20 of the die (i.e., including a sidewall of the protruding part 100b of the substrate 100, a sidewall of the heat dissipation filling structure 106 and a sidewall of the barrier layer 105) are substantially aligned with each other in a direction perpendicular to the main surface of the die. Similar to the previous embodiments, the heat dissipation filling structure 106 extends into the substrate 100 from the back surface of the substrate 100 in a direction perpendicular to the main surface of the die, and extends through the substrate 100 in a direction parallel to the main surface of the die, and has opposite sidewalls exposed by the substrate. In this embodiment, the cutting process only forms trench(es) for being filled with the heat dissipation filling structure, without forming a substrate recess by cutting and removing the edge part of the substrate.

In this embodiment, a thermal interface material layer 301 is formed on the back surface T2 of the die 120c, and is in contact with surfaces of the protruding part 100b of the substrate 100, the heat dissipation filling structure 106, and the barrier layer 105 away from the body part 100a (i.e., the top surface illustrated in the figure). The thermal dissipation component 300 is attached to the die 120c through the thermal interface material layer 301. In this embodiment, since the die 120c is not provided with a recess, accordingly, the thermal dissipation component 300 may not be provided with a heat dissipation protrusion. However, the present disclosure is not limited thereto.

Referring to FIG. 17, in some other embodiments, the package structure 500g is similar to the package structure 500a, with the difference that in the package structure 500g, the substrate 100 of the die 120d is not provided with a heat dissipation filling structure and a barrier layer; the first cutting process only forms a substrate recess, without forming a trench for being filled with a heat dissipation filling structure.

In this embodiment, the die 120d has a substrate recess RS, and the back surface T2 and the sidewall S20 of the die are both surfaces of the protruding part 100b of the substrate 100. The thermal interface material layer 301 is disposed on the back side of the die 120 and filled in the recess RS of the substrate 100, and is in contact with the back surface T2, the back surface T1 and the sidewall S20 of the substrate 100. Similar to the previous embodiments, the thermal dissipation component 300 has a heat dissipation protrusion 300b extending into the recess RS. The relative positional relationships among the thermal dissipation component 300, the thermal interface material layer 301 and the die 102d are similar to those of the previous embodiments, which will not be described here.

In the embodiments of the present disclosure, the heat dissipation performance of the die can be improved by disposing at least one of the heat dissipation filling structure and the substrate recess in the substrate of the die, and at least one of the trench(es) for the heat dissipation filling structure to fill therein and the substrate recess can be formed through a cutting process, so that the process can be simplified, the cost can be reduced, the production efficiency can be improved, and the yield can thus be increased; furthermore, a trench with a larger size can be formed by using the cutting process, so that the content of the heat dissipation filling material with greater thermal conductivity in the die can be increased, thereby further reducing the thermal resistance of the die, and the heat dissipation performance of the die can be improved. It should be understood that, the structural features such as the shapes and positions of the substrate trench(es) and the corresponding heat dissipation filling structure, as well as the structural features such as the shape and position of the substrate recess described in the above embodiments are only for illustration, and the present disclosure is not limited thereto. It should be understood that, the shapes and positions of the trenches and the recess of the substrate can be adjusted based on product requirements, as long as the trenches of the substrate as formed can be filled with heat dissipation materials having higher thermal conductivity and the substrate recess as formed can increase the heat dissipation area of the die to achieve the effect of improving the heat dissipation performance of the die; alternatively, the substrate recess may not be formed, while the thermal interface material layer and the heat dissipation protrusion may extend to cover the sidewall of the substrate, so as to increase the heat dissipation area of the die and improve the heat dissipation performance thereof, and all these modifications are covered within the scope of protection of the present disclosure.

The following statements should be noted: (1) the accompanying drawings related to the embodiment(s) of the present disclosure involve only the structure(s) in connection with the embodiment(s) of the present disclosure, and other structure(s) can be referred to common design(s); (2) in case of no conflict, features in one embodiment or in different embodiments of the present disclosure can be combined.

The above, are only specific embodiments of the present disclosure, but the scope of protection of the present disclosure is not limited thereto, and any variation or substitution readily conceivable by any person skilled in the art within the technical scope disclosed in the present disclosure shall be covered by the scope of protection of the present disclosure. Accordingly, the scope of protection of the present disclosure shall be defined by the scope of protection of the claims.

1. A package structure, comprising:
a die, comprising a substrate and a device layer, wherein the substrate has a front side and a back side opposite to each other in a first direction perpendicular to a main surface of the die, and the device layer is disposed at the front side of the substrate;
a thermal interface material layer, disposed on the back side of the substrate; and
a thermal dissipation component, attached to the die through the thermal interface material layer,
wherein the die further comprises at least one of a heat dissipation filling structure and a substrate recess, the heat dissipation filling structure is embedded in the substrate and has an exposed part exposed at a sidewall of the substrate; the substrate recess is recessed from the back side of the substrate towards the device layer.

2. The package structure according to claim 1, wherein the heat dissipation filling structure extends through the substrate in a second direction parallel to the main surface of the die, and the exposed part of the heat dissipation filling structure comprises sidewalls opposite in the second direction, wherein the exposed part of the heat dissipation filling structure is in contact with the thermal interface material layer.

3. The package structure according to claim 1, wherein a part of the thermal interface material layer and a part of the thermal dissipation component extend into the substrate recess.

4. The package structure according to claim 1, wherein a contact area between the thermal interface material layer and the die is greater than an area of an orthographic projection of the substrate on the main surface of the die in the first direction, and a contact area between the thermal dissipation component and the thermal interface material layer is greater than the area of the orthographic projection of the substrate.

5. The package structure according to claim 1, wherein a part of the thermal interface material layer extends to cover and contact a sidewall of the substrate and the exposed part of the heat dissipation filling structure, and the thermal dissipation component has a heat dissipation body part and a heat dissipation protrusion, the heat dissipation protrusion is protruded from the heat dissipation body part and towards the die, in contact with the part of the thermal interface material layer, and overlapped with the substrate in a horizontal direction parallel to the main surface of the die.

6. The package structure according to claim 5, wherein in the horizontal direction, the part of the thermal interface material layer and the heat dissipation protrusion laterally surround the substrate of the die.

7. The package structure according to claim 5, wherein the sidewall of the substrate and the exposed part of the heat dissipation filling structure define a portion of a boundary of the substrate recess, and the part of the thermal interface material layer and at least a part of the heat dissipation protrusion are located in the substrate recess.

8. The package structure according to claim 7, wherein the substrate recess has a first sub-recess and a second sub-recess, a depth of the first sub-recess is greater than a depth of the second sub-recess, and the heat dissipation protrusion comprises a protrusion body and a sub-protrusion, the sub-protrusion is protruded from the protrusion body in the first direction and extends into the first sub-recess of the substrate recess.

9. The package structure according to claim 1, wherein the die has a first sidewall and a second sidewall, and the second sidewall is closer to a center of the die than the first sidewall to the center of the die;
the die has a first back surface and a second back surface at the back side of the substrate, the second back surface is further away from the device layer than the first back surface to the device layer, and the substrate recess is defined by the first back surface and the second sidewall of the die.

10. The package structure according to claim 9, wherein
the thermal interface material layer comprises a thermal interface body part and a thermal interface extension part, wherein the thermal interface body part is in contact with the second back surface of the die, and the thermal interface extension part is in contact with the first back surface and the second sidewall of the die; and
the thermal dissipation component has a heat dissipation body part and a heat dissipation protrusion, wherein the heat dissipation body part is in contact with the thermal interface body part, and the heat dissipation protrusion is in contact with the thermal interface extension part.

11. The package structure according to claim 9, wherein the substrate comprises a body part and a protruding part located on a side of the body part away from the device layer, the first sidewall of the die comprises a sidewall of the body part of the substrate, and the second sidewall of the die comprises a sidewall of the protruding part of the substrate and a sidewall of the heat dissipation filling structure.

12. The package structure according to claim 11, wherein the first back surface of the die comprises a surface of the body part of the substrate close to the thermal interface material layer, and the second back surface of the die comprises a surface of the protruding part of the substrate close to the thermal interface material layer or comprises surfaces of both the protruding part of the substrate and the heat dissipation filling structure close to the thermal interface material layer.

13. The package structure according to claim 1, wherein the heat dissipation filling structure extends into the substrate from the sidewall of the substrate, and surfaces of the heat dissipation filling structure opposite in the first direction are covered by the substrate, and a part of the substrate is located between the heat dissipation filling structure and the thermal interface material layer in the first direction.

14. The package structure according to claim 1, wherein a thermal conductivity of the heat dissipation filling structure is greater than a thermal conductivity of the substrate.

15. The package structure according to claim 1, further comprising:
a package substrate, electrically connected to the die and disposed on a side of the die opposite to the thermal interface material layer.

16. A method of manufacturing a package structure, comprising:
providing a die comprising a substrate and a device layer, wherein the substrate has a front side and a back side opposite to each other in a first direction perpendicular to a main surface of the die, and the device layer is disposed at the front side of the substrate;
forming at least one of a heat dissipation filling structure and a substrate recess in the substrate of the die, comprising: performing a first cutting process on the die to cut and remove a part of the die, and forming at least one of a trench and the substrate recess in the substrate of the die, wherein the trench is configured for being filled with the heat dissipation filling structure;
disposing a thermal interface material layer on the back side of the substrate; and
attaching a thermal dissipation component to the die through the thermal interface material layer.

17. The method of manufacturing the package structure according to claim 16, wherein performing the first cutting process on the die comprises:
performing a cutting process from the back side of the substrate along a first cutting path across the die to remove a first part of the substrate and form the trench, wherein the first part of the substrate comprises a middle part of the substrate.

18. The method of manufacturing the package structure according to claim 16, wherein performing the first cutting process on the die comprises:
performing a cutting process from the back side of the substrate along a second cutting path across the substrate of the die to remove a second part of the substrate and form the substrate recess, wherein the second part comprises an edge part of the substrate;
wherein the thermal interface material layer and the thermal dissipation component extend into the substrate recess.

19. The method of manufacturing the package structure according to claim 16, wherein performing the first cutting process on the substrate comprises:
cutting and removing an edge part of the substrate to form the substrate recess; and
performing a laser drilling process on the substrate from a sidewall of the substrate to remove a part of the substrate and form the trench in the substrate.

20. The method of manufacturing the package structure according to claim 16, wherein providing the die comprises:
providing a wafer comprising a plurality of dies and having a scribe line between the plurality of dies, wherein the first cutting process comprises cutting the wafer along a cutting path extending across the plurality of dies, and
the manufacturing method further comprises:
after forming at least one of the heat dissipation filling structure and the substrate recess, and before disposing the thermal interface material layer on the back side of the substrate, performing a second cutting process on the wafer along the scribe line to singulate the plurality of dies, wherein a cutting depth of the first cutting process is smaller than a cutting depth of the second cutting process.
